(19) United States
(12) Patent Application Publication
(10) Pub. No.: US 2024/0363262 A1
(43) Pub. Date: Oct. 31, 2024

(54) CARBON NANOTUBE-TO-METAL ASSEMBLIES

(71) Applicant: Wootz, Inc., Cleveland, TX (US)

(72) Inventors: Elie Amram Bengio, Houston, TX (US); Alexander Joseph Marks, Houston, TX (US); Charles Marks, Johnson City, TX (US)

(73) Assignee: Wootz, Inc., Cleveland, TX (US)

(21) Appl. No.: 18/647,973

(22) Filed: Apr. 26, 2024

Related U.S. Application Data
(60) Provisional application No. 63/462,926, filed on Apr. 28, 2023.

(51) Int. Cl. H01B 1/04; C01B 32/168; C23C 14/18; C25D 5/54

(52) U.S. Cl. CPC H01B 1/04; C01B 32/168; C23C 14/185; C25D 5/54; C01B 2202/08; C01B 2202/22; C01B 2202/30; C01P 2004/02; C01P 2004/54; C01P 2006/10

(57) ABSTRACT

The present disclosure provides carbon nanotube (CNT)-to-metal assemblies comprising a carbon nanotube (CNT) component connected to a metal component, and methods for preparing them. The assemblies may be connected through a CNT-to-metal connector that may comprise a CNT connector pad.

### CROSS REFERENCE TO RELATED APPLICATIONS

This application claims priority to U.S. Provisional Patent Application No. 63/462,926, filed Apr. 28, 2023, which is hereby incorporated by reference in its entirety.

### FIELD

Described herein are carbon nanotube (CNT)-to-metal assemblies comprising a carbon nanotube (CNT) component connected to a metal component, and methods for preparing them. The CNT component may be connected to the metal component via a CNT-to-metal connector which optionally may comprise a CNT connector pad.

### BACKGROUND

Carbon nanotube (CNT) materials such as fibers, films and coatings are being developed with properties, such as electrical conductivity, that are enabling their use across a broad range of applications. CNTs have primarily been used as additives to enhance the properties of other materials, such as polymers, metals, and ceramics. However, with the emergence of pristine CNT conductors comes the challenge of interfacing these carbon-based conductors with traditional metal-based electronics.

Challenges associated with connecting a CNT component (e.g., a component comprising a CNT material) with a metal component are multi-faceted, and originate from factors such as (1) poor wettability of commonly used solders and brazes on carbon materials; (2) inadequate composition, structure and properties of the CNT material (3) dissimilar properties of the CNT material and the metal component at the interface and (4) challenging uses (e.g., those involving chemically aggressive environments and/or involving mechanical/thermal cycling). For example, poor wetting of carbon allotropes by liquid metals at common solder temperatures is a known problem where the typical contact angle values are well above 90 degrees. This may be due to the absence of chemical bonds at the carbon/metal interface, where weak van-der-Waals forces provide an exclusively physical bonding mechanism. On the other hand, good wetting of a liquid metal on a solid substrate is observed if the interfacial bond is strong (e.g., chemical in nature), as shown in the Young-Dupre equation. Generally, in the case of applying a liquid metal solder to a solid metal surface the interfacial bond is metallic and therefore can lead to good wetting (e.g., a contact angle of 1-20 degrees), regardless of the miscibility between the liquid and solid. In some circumstances, a metal (e.g., Al, Ti, Zr, Cr, W, or Mo) can react with carbon to form a carbide species with a stronger interfacial bond. However, this typically comes at the expense of contact resistance, as such compounds (e.g., carbides) are usually much less electrically conductive than the pure metal. A known example is the reaction between aluminum and carbon to form aluminum carbide (Al₄C₃). This carbide layer is responsible for a significant increase in electrical resistance and corresponding decrease in efficiency of devices that rely on current transport across such an interface.

With respect to the CNT materials comprising a CNT component, their high surface area coupled with large contact angle values can lead to the formation of a partly solid-liquid and partly solid-gas interface, resulting in entrained void spaces. These entrained void spaces can decrease the contact area, resulting in poor contact resistance, and can lead to detachment of the solidified metal from the CNT substrate (e.g., the CNT materials). Another source of void spaces can be improper processing and alignment of individual CNTs within the material, as well as the presence of impurities left over from the CNT synthesis process, such as non sp2-hybridized carbon and metal catalyst nanoparticles. Void spaces and improper alignment in the CNT material can result in a lower electrical conductivity, leading to poor performance of the connector assembly. Improper alignment can also lead to increased void spaces, since alignment facilitates a hexagonal close packed configuration of carbon nanotubes. In certain applications, void spaces can introduce a parasitic capacitance which is detrimental and must be corrected or compensated in the circuit, therefore increasing system cost and complexity. Additionally, the presence of metallic particle impurities (e.g., metallic particle impurities left over from CNT synthesis processes) may adversely affect connector performance in other ways. For example, ferromagnetic particles, such as iron, are popular catalysts in CNT synthesis, but the presence of ferromagnetic particles is highly problematic and can manifest itself in the form of passive intermodulation (PIM) distortion in a transmitted AC signal.

Further, CNTs and metals have certain dissimilar material properties which also can be responsible for poor CNT-to-metal connector performance, particularly in challenging use cases (e.g., those involving chemically aggressive environments and/or involving mechanical/thermal cycling). Typically, electrical systems are designed in a way that protects the connection sites. For example, by utilizing strain relief and/or placing the connection sites away from flex zones, and/or via proper thermal insulation and management. However, in applications that involve significant mechanical and/or thermal loads, the connections may be required to endure some amount of mechanical and/or thermal loading due to spatial design constraints. Applications with a cyclical load are particularly challenging. Dissimilar flexural properties can lead to deformation of the more flexible, softer CNT material under repeated bending contact with more rigid, harder metals. Additionally, dissimilar thermal expansion properties, known to be positive in the case of metals and negligible in the case of CNTs, can lead to thermally induced stresses which decrease contact area and in turn increase contact resistance as the metal-CNT interface repeatedly undergoes uneven deformation.

As noted above, these issues have a negative impact on CNT-to-metal connector performance. For example, in steady current applications, increased power loss at the connector, mechanical failure of the connector, and/or thermal damage to surrounding materials may occur, all of which may ultimately lead to device failure. For alternating current applications, particularly those where high-fidelity signal transmission is required, additional performance deterioration in the form of increased signal attenuation, due to PIM distortion, and/or decreased Signal-to-Noise Ratio (SNR), are also problematic.

Thus, there remains a need for carbon nanotube (CNT)-to-metal assemblies comprising a carbon nanotube (CNT) component connected to a metal component, and methods for preparing them.

### SUMMARY

Described herein are carbon nanotube (CNT)-to-metal assemblies comprising a carbon nanotube (CNT) component connected to a metal component, and methods for preparing them. The assemblies may be connected through a CNT-to-metal connector that may comprise a CNT connector pad.

In one aspect, provided herein is an assembly comprising a carbon nanotube (CNT) component connected to a metal component, wherein the CNT component comprises a CNT material comprising at least 90 wt %, at least 95 wt %, or at least 99 wt % carbon nanotubes (CNTs), wherein the CNTs or CNT material exhibit one or more or all of the following properties: (a) the CNT material has an electrical conductivity of at least 1 MS/m, at least 5 MS/m, or at least 10 MS/m; (b) the CNTs have an average aspect ratio of at least 1000, at least 5000, or at least 10,000; and (c) the CNTs have an average G/D ratio of at least 1, at least 10, or at least 100.

In some embodiments, the CNT component may be connected to the metal component through a CNT-to-metal connector, wherein the CNT-to-metal connector comprises a material selected from graphene, metals, and metal-containing epoxies.

In some embodiments, the CNT component may be connected to the metal component through a CNT connector pad, wherein the CNT connector pad comprises a CNT material comprising at least 90 wt %, at least 95 wt %, or at least 99 wt % carbon nanotubes (CNTs), and wherein the CNTs or CNT material exhibit one or more or all of the following properties: (a) the CNT material has an electrical conductivity of at least 1 MS/m, at least 5 MS/m, or at least 10 MS/m; (b) the CNTs have an average aspect ratio of at least 1000, at least 5000, or at least 10,000; and (c) the CNTs have an average G/D ratio of at least 1, at least 10, or at least 100. The CNT connector pad may be connected to the metal component through a CNT-to-metal connector, wherein the CNT-to-metal connector comprises a material selected from graphene, metals, and metal-containing epoxies. The CNT connector pad may be comprised of a single layer of aligned or unaligned CNT material and may have a thickness of from 1 to 10 μm. The CNT connector pad may be comprised of a plurality of layers of aligned CNT material and may have a thickness of from 1 μm to 0.5 mm. The CNT connector pad may be comprised of a plurality of layers of aligned CNT material, wherein the plurality of layers comprises a first layer of said CNT material and a second layer of said CNT material, optionally wherein said first and second layers are arranged in a different orientation relative to each other. The CNT connector pad may be comprised of a plurality of layers of aligned CNT material, wherein the plurality of layers comprises an outer layer of said CNT material and one or more intermediate layers of said CNT material, optionally wherein one or more of said intermediate layers are sputter-coated or electroplated with a thin metal layer, optionally wherein the metal is one or more selected from Cu, In, Ni, Ag, Au, Sn, Al, Zn, Pt, Pd, Pb, Mo, Mg, Rh, and W, further optionally wherein the metal is selected from Cu, In, or Ni.

In accordance with any embodiments, the CNT material of the CNT component may further exhibit one or more or all of the following properties: (i) the CNT material comprises less than 20 wt %, less than 10 wt %, or less than 5 wt % of non-sp2-hybridized carbon material, or non-sp2-hybridized carbon material is absent from the CNT material; (ii) the CNT material comprises less than 10 wt %, less than 5 wt %, or less than 2 wt % of metallic particle impurities, or metallic particle impurities are absent from the CNT material; and (iii) the CNT material has a density of at least 1 g/cm³, at least 1.2 g/cm³, or at least 1.4 g/cm³.

In accordance with any embodiments, the CNT material of the CNT connector pad may further exhibit one or more or all of the following properties: (i) the CNT material comprises less than 20 wt %, less than 10 wt %, or less than 5 wt % of non-sp2-hybridized carbon material, or non-sp2-hybridized carbon material is absent from the CNT material; (ii) the CNT material comprises less than 10 wt %, less than 5 wt %, or less than 2 wt % of metallic particle impurities, or metallic particle impurities are absent from the CNT material; and (iii) the CNT material has a density of at least 1 g/cm³, at least 1.2 g/cm³, or at least 1.4 g/cm³.

In accordance with any embodiments, the CNT component of a CNT-to-metal assembly described herein may be in a form selected from a film, a fiber, a foam, and a coating.

In accordance with any embodiments, the metal component of a CNT-to-metal assembly described herein may be selected from a metal matrix, metal wires, metal cables, ring terminals, circuit board terminals, quick-disconnect terminals, spade terminals, hook terminals, snap plug terminals, battery terminals, battery terminal clamps, battery springs, grounding blocks, butt splices, wire ferrules, terminal blocks, compression lugs, set screw lugs, BNC (Bayonet Neill-Concelman) connectors, TNC (Threaded Neill-Concelman) connectors, RCA (Radio Corporation of America) connectors, SMA (SubMiniature version A) connectors, SMC (SubMiniature version C) connectors, FFC (Flat Flexible Cable) connectors, FPC (Flexible Printed Circuit) connectors, DIN (Deutsches Institut fur Normung) connectors, and F-type connectors.

In accordance with any embodiments, the CNT component of a CNT-to-metal assembly described herein may be selected from display electrodes, touch screen electrodes, energy harvesting electrodes, solar cell electrodes, battery electrodes, static-dissipative elements, grounding elements, resistive heating elements, strain sensing elements, chemical sensor elements, the radiating element of an antenna, the ground plane of an antenna, the outer shield of a coaxial cable, the inner conductor of a coaxial cable, smart coatings for in-situ monitoring of abrasion, resistive elements for sensors, capacitive elements for sensors, inductive elements for sensors, biosensing elements for muscular activity, biosensing elements for neural activity, muscular stimulation electrodes, neural stimulation electrodes, DC power cables, DC transmission lines, AC power cables, AC transmission lines, field emitters, transformer coils, DC motor coils, electronic textiles, resistors, transistors, conductors, capacitors, and inductors.

In accordance with any embodiments, the CNT-to-metal assembly described herein may exhibit one or more or all of the following properties: a signal attenuation of 20 dB to 30 dB, 10 dB to 20 dB, or 5 dB to 10 dB; a signal to noise ratio of 2:1 to 5:1, 5:1 to 20:1, or 20:1 to 100:1; a phase shift relative to the signal going into the assembly of less than pi/12 rad, less than pi/24 rad, or less than pi/96 rad; and a temperature difference as compared to the steady state temperature of the metal component of less than 25° C., less than 15° C., or less than 5° C.

In another aspect, provided herein is a method of making an assembly (e.g., a CNT-to-metal assembly) in accordance with any of the foregoing embodiments, the method comprising contacting the CNT component and the metal component at an interface to form a junction, and further comprising one or more or all of the following steps: wrapping or tying the junction with a CNT fiber or film or foam; electroplating a surface of the CNT material of the CNT component with a metal; sputter-coating a surface of the CNT material of the CNT component with a metal; wetting a surface of the CNT material of the CNT component prior to a soldering or brazing step; soldering or brazing the CNT material of the CNT component to the metal component; providing a conductive, metal-filled epoxy at the interface; applying a reactive foil comprising a metal solder with one or more selected from pressure, current and heat at the interface; and potting, heat shrinking, or molding the assembly. The metal may be one or more selected from Cu, In, Ni, Ag, Au, Sn, Al, Zn, Pt, Pd, Pb, Mo, Mg, Rh, and W, optionally wherein the metal is selected from Cu, In, or Ni.

In some embodiments, a method of making an assembly (e.g., a CNT-to-metal assembly) in accordance with any of the foregoing embodiments may comprise contacting the CNT component and the CNT-to-metal connector at an interface to form a junction, and may further comprise one or more or all of the following steps: wrapping or tying the junction with a CNT fiber or film or foam; electroplating a surface of the CNT material of the CNT component with a metal; sputter-coating a surface of the CNT material of the CNT component with a metal; and wetting a surface of the CNT material of the CNT component prior to a soldering or brazing step; soldering or brazing the CNT material of the CNT component to the CNT-to-metal connector; providing a conductive, metal-filled epoxy at the interface; applying a reactive foil comprising a metal solder with one or more selected from pressure, current and heat at the interface; and potting, heat shrinking, or molding the assembly. The metal may be one or more selected from Cu, In, Ni, Ag, Au, Sn, Al, Zn, Pt, Pd, Pb, Mo, Mg, Rh, and W, optionally wherein the metal is selected from Cu, In, or Ni.

In some embodiments, a method of making an assembly (e.g., a CNT-to-metal assembly) in accordance with any of the foregoing embodiments may comprise contacting the CNT component and the CNT connector pad at an interface, and further comprising one or more or all of the following steps: evaporating a solvent at the interface to connect the CNT component to the CNT connector pad via capillary action, optionally wherein the solvent is one or more selected from water, acetone, methyl ethyl ketone, diethyl ether, chloroform, n-hexane, ethanol, ethylene glycol, xylene, toluene, THF (tetrahydrofuran), NMP (N-Methyl-2-pyrrolidone), and HFEs (hydrofluorocthers); solvent-welding the CNT connector pad to the CNT component using an acid; and mechanically attaching the CNT connector pad to the CNT component.

In some embodiments, the method may further comprise contacting the CNT connector pad and the metal component at an interface to form a junction of the assembly, and may further comprise one or more or all of the following steps: wrapping or tying the junction with a CNT fiber or film or foam; electroplating a surface of the CNT material of the CNT connector pad with a metal; sputter-coating a surface of the CNT material of the CNT connector pad with a metal; and wetting a surface of the CNT material of the CNT connector pad prior to a soldering or brazing step; soldering or brazing the CNT material of the CNT connector pad to the metal component; providing a conductive, metal-filled epoxy at the interface; applying a reactive foil comprising a metal solder with one or more selected from pressure, current and heat at the interface; and potting, heat shrinking, or molding the assembly. The metal may be one or more selected from Cu, In, Ni, Ag, Au, Sn, Al, Zn, Pt, Pd, Pb, Mo, Mg, Rh, and W, optionally wherein the metal is selected from Cu, In, or Ni.

In some embodiments, a method of making an assembly (e.g., a CNT-to-metal assembly) in accordance with any of the foregoing embodiments may comprise providing a CNT connector pad on a surface of a metal component by wrapping or tying a pre-formed CNT film or foam around the metal component; wrapping or tying a CNT fiber around the metal component; or forming a CNT film directly on a surface of the metal component from a fluid phase.

In some embodiments, a method of making an assembly (e.g., a CNT-to-metal assembly) in accordance with any of the foregoing embodiments may comprise transferring a CNT film or CNT foam from a transfer sleeve to a metal component, optionally wherein the transferring comprises one or more or all of the following steps: wetting a surfaces of the metal component; inserting the metal component into the CNT film- or CNT foam-loaded transfer sleeve; compressing the transfer sleeve onto/around the metal component; and withdrawing the transfer sleeve from the metal component to obtain the metal component provided with a CNT connector pad comprised of the CNT film or CNT foam. In some embodiments, the method further comprises loading a transfer sleeve with a pre-formed CNT film or CNT foam. In some embodiments, the loading comprises one or more or all of the following steps: providing the CNT film or CNT foam around a support; wetting an inside surface of the transfer sleeve; inserting the support into the sleeve; compressing the sleeve onto/around the support; and withdrawing the support from the sleeve to obtain the CNT film- or CNT foam-loaded sleeve. In other embodiments, the loading comprises one or more or all of the following steps: preparing the CNT film or CNT foam in situ inside the transfer sleeve by forming the CNT film or CNT foam directly on interior surfaces of the transfer sleeve from a fluid phase.

In some embodiments, the method may further comprise promoting connection between the CNT connector pad and metal component by one or more of the following steps: evaporating a solvent at an interface between the CNT connector pad and metal component to promote densification via capillary action, optionally wherein the solvent is one or more selected from water, acetone, methyl ethyl ketone, diethyl ether, chloroform, n-hexane, ethanol, ethylene glycol, xylene, toluene, THF (tetrahydrofuran), NMP (N-Methyl-2-pyrrolidone), and HFEs (hydrofluoroethers); applying pressure to the interface; applying current to the interface; and applying heat to the interface.

In some embodiments, the method may further comprise contacting the CNT component and the CNT connector pad at an interface, and promoting connection between the CNT component and CNT connector pad by one or more or all of the following steps: evaporating a solvent at an interface between the CNT connector pad and CNT component to promote densification via capillary action, optionally wherein the solvent is one or more selected from water, acetone, methyl ethyl ketone, diethyl ether, chloroform, n-hexane, ethanol, ethylene glycol, xylene, toluene, THF (tetrahydrofuran), NMP (N-Methyl-2-pyrrolidone), and HFEs (hydrofluoroethers); solvent-welding the CNT connector pad to the CNT component using an acid; and mechanically attaching the CNT connector pad to the CNT component.

Also provided herein is an assembly comprising a carbon nanotube (CNT) component connected to a CNT connector pad, wherein each of the CNT component and the CNT connector pad independently comprises a CNT material comprising at least 90 wt %, at least 95 wt %, or at least 99 wt % carbon nanotubes (CNTs), wherein the CNTs or CNT material exhibit one or more or all of the following properties: the CNT material has an electrical conductivity of at least 1 MS/m, at least 5 MS/m, or at least 10 MS/m; the CNTs have an average aspect ratio of at least 1000, at least 5000, or at least 10,000; and the CNTs have an average G/D ratio of at least 1, at least 10, or at least 100.

Also provided herein is an assembly comprising a metal component connected to a CNT connector pad, wherein the CNT connector pad comprises a CNT material comprising at least 90 wt %, at least 95 wt %, or at least 99 wt % carbon nanotubes (CNTs), wherein the CNTs or CNT material exhibit one or more or all of the following properties: the CNT material has an electrical conductivity of at least 1 MS/m, at least 5 MS/m, or at least 10 MS/m; the CNTs have an average aspect ratio of at least 1000, at least 5000, or at least 10,000; and the CNTs have an average G/D ratio of at least 1, at least 10, or at least 100.

In accordance with any embodiments, a metal component may comprise one or more metals selected from Cu, In, Ni, Ag, Au, Sn, Al, Zn, Pt, Pd, Pb, Mo, Mg, Rh, and W.

### BRIEF DESCRIPTION OF THE DRAWINGS

FIG. 1 provides digital photographs of masked electroplating of different metals on CNT films. Images a-b illustrate that different metals can be electroplated onto CNT films with good control over their shape via masking. Image a shows Cu electroplated onto CNT film in various shapes commonly used for soldering pads. Image b shows Cu, In, Zn, and Ni electroplated onto CNT film in various shapes. Image c is a polarized optical micrograph of electroplated versus bare CNT interface, showing the electroplating process on CNT films preserves their fibrillar microstructure and high surface area. Without being bound by theory, it is believed that metals normally would not wet CNTs so readily, given their irregular surface topology. The absence of metal droplet formation indicates good coverage of the CNT structure during the electroplating process.

FIG. 2 provides a digital photograph of Ni-electroplated CNT fibers. It shows that despite the high curvature at the surface of thin CNT fibers (<100 μm), their high electrical conductivity and surface area are sufficient to enable solution electroplating of Ni.

FIGS. 3A-3C show electroplated Cu connector pads can serve to provide a surface that is readily wetted by common lead-free Sn solder. FIG. 3A provides a digital photograph of an electroplated copper pad with wetted solder connecting to a 10 Ω resistor leg. FIG. 3B shows a laser and optical micrograph of Sn solder droplet on a Cu connector pad electroplated on CNT film. FIG. 3C provides a 3D laser surface profile of an Sn solder droplet showing the reference endpoints.

FIG. 3D provides a 2D line profile used for an illustrative measurement of the contact angle between the Sn solder droplet and the connector pad, providing a direct measurement of an excellent wetting contact angle (<45 degrees) between the solder droplet and the electroplated Cu connector pad, which is itself parallel to the underlying CNT film.

FIG. 3E provides a digital photograph of an illustrative CNT trace for AC signal transmission on a PCB (printed circuit board). The size of the Cu connector pads is about 1 mm in diameter by using constant current electroplating (substantially finer control can be effected by employing other methods such as pulsed and reverse pulsed electroplating). Without being bound by theory, it is believed that in AC signal transmission applications, the presence of ferromagnetic compounds such as Fe can introduce distortions to the signal such as passive intermodulation (PIM), so advantageously the metal content (usually due to leftover metal catalyst particles) in the CNT film is negligible in such applications.

FIGS. 4A-4B illustrate that electroplated CNT fibers can be readily wetted by common solder (e.g., a solder ring found in solder-loaded heat shrink tubing). FIG. 4A provides a digital photograph of a Ni-electroplated CNT fiber soldered to a braided tinned copper wire. FIG. 4B provides a digital photograph of a Ni-electroplated CNT fiber connected to a 10 Ω resistor leg via solder-loaded heat shrink tubing. The circles are provided to show sections of electroplated fiber being wetted by the solder. Once its working temperature is reached, the solder wets and travels up the electroplated fiber, forming a low contact angle at the interface.

FIG. 5 depicts illustrative methods of ensuring good electrical contact between metal wires/connectors and CNT materials (e.g., CNT films and fibers) in accordance with the present disclosure. Image a provides a photograph of a CNT connector pad as disclosed herein in the form of a CNT film being wrapped around the exposed end of a metal wire. Image b shows the corresponding exposed ends of the CNT-wrapped metal wire in Image a. Images a-b illustrate that a metallic surface can be wrapped with CNT film (solid state), and that coating CNTs onto a metallic surface in a fluid phase can be achieved to form a CNT connector pad as disclosed herein in the form of a CNT film formed on the metallic surface. Image c shows an end-launch male SMA (SubMiniature version A) connector wrapped with a CNT connector pad as disclosed herein in the form of a CNT film that is used to interface between a (metal) coaxial cable and a CNT thin film patch antenna (a “CNT component”). The network analyzer is displaying the S11 value as a function of frequency, with a minimum at resonance of −18.8 dB. It shows that when the center pin and ground legs of an SMA connector are wrapped in CNT film and mechanically fastened to the feed and ground plane of a CNT patch antenna respectively, the resulting connector losses are negligible such that over 99.99% of the EM energy is transmitted to the antenna, as indicated by the minimum S11 value at resonance. Without being bound by theory, it is believed that the mechanical properties of the CNT film enable it to be mechanically compressed without being damaged, and the high electrical conductivity and high surface area enable minimum losses at the interface. Additionally, in RF applications, the presence of ferromagnetic compounds (e.g., Fc) can introduce additional loss mechanisms, so the metal content (usually due to leftover metal catalyst particles) in the CNT film need to be negligible.

FIGS. 6A-6B provide illustrative approaches to form a CNT-to-metal assembly, which approaches can be used individually or in combination. A CNT-to-metal assembly can be prepared by directly attaching a CNT material to a metal component, by preparing the surface of a CNT material using a CNT connector pad as disclosed herein, or by preparing the surface of the metal component with a CNT material, or any combination of the aforementioned methods, as disclosed herein. FIG. 6A provides a block diagram showing an illustrative method of forming a connected CNT-to-metal assembly by using a CNT connector pad. FIG. 6B provides a block diagram showing an illustrative method of forming a connected CNT-to-metal assembly by using a CNT material to prepare the surface of a metal component.

FIGS. 7-9 provide illustrative schematic figures showing cross-sections of certain layered structures. FIG. 7 shows the layered structure of solder on electroplated metal on CNT film. FIG. 8 shows a cross-section of electroplated CNT fiber. FIG. 9 shows a cross-section of CNT film/fiber wrapped around the wire.

FIG. 10 illustrates use of a transfer sleeve to connect a CNT connector pad to a metal component, wherein the CNT connector pad is in the form of a pre-formed CNT film. Panel a shows inserting a rod coated with a CNT film into a transfer sleeve. Panel b shows applying compression and spraying water to release the CNT film from the rod and transfer to the CNT film to the interior of the transfer sleeve. Panel c shows the transfer sleeve loaded with the CNT film. Panel d shows inserting a metal component into the transfer sleeve loaded with the CNT film. Panel e shows applying compression and spraying water to release the CNT film from the transfer sleeve and transfer the CNT film to the metal component, thereby connecting a CNT connector pad in the form of a pre-formed CNT film to the metal component. Panel f shows additional steps that may be taken to further connect the CNT connector pad and the metal component as described in more detail below.

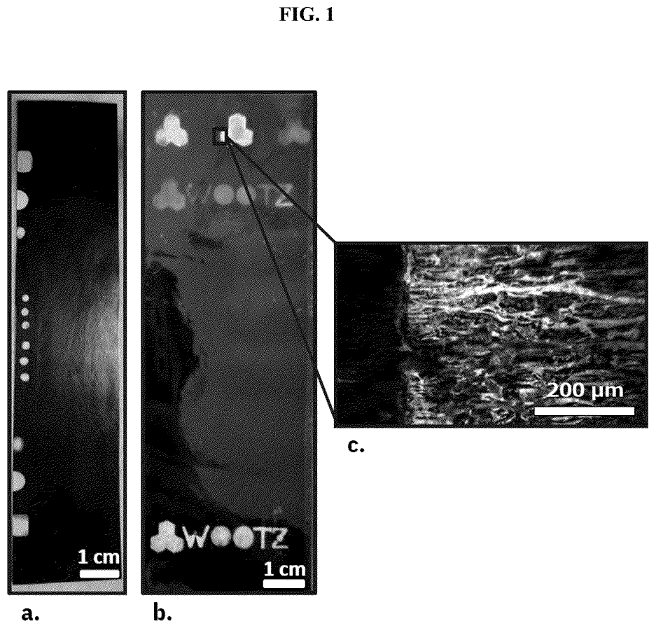

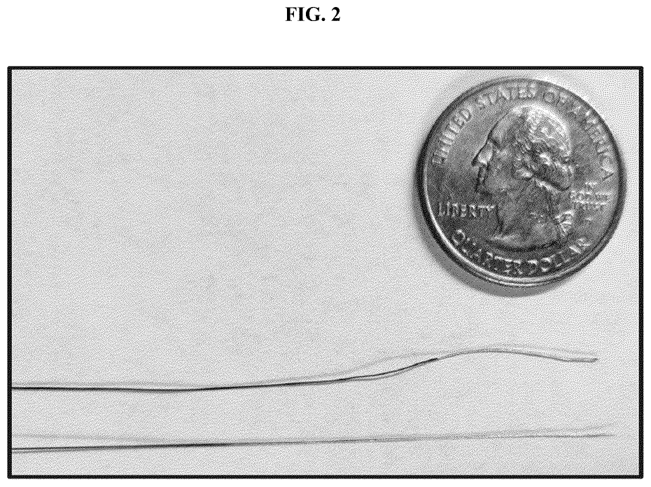

### DETAILED DESCRIPTION

The present disclosure provides CNT materials, CNT-to-metal connectors, and CNT connector pads, each of which can be suitable for connecting a CNT component (e.g., a CNT component comprising or comprised of a CNT material as described herein) to a metal component, providing CNT-to-metal assemblies. Also provided herein are methods for preparing the same, as well as CNT-to-metal assemblies, and devices (products) containing them. The CNT-to-metal assemblies provided herein generally comprise a carbon nanotube (CNT) component connected to a metal component. The CNT component can be connected to the metal component through a CNT-to-metal connector which may comprise a CNT connector pad as described herein.

CNT-to-metal assemblies as described herein may be used in various environments, including DC (direct current), low-power, non-aggressive environments (e.g., digital electronics); DC, high-power, non-aggressive environments (e.g., power electronics); AC (alternating current), low-power, non-aggressive environments (e.g., coax signal transmission); AC, high-power, non-aggressive environments (e.g., wireless RF (radio frequency)); DC, high-power, aggressive environments (e.g., subsea cables or transmission lines); and AC, low-power, aggressive environments (e.g., coax cables in aerospace).

Aligned CNT materials have unique combinations of material properties that make them attractive for use as lightweight conductor and/or conductor reinforcement materials. For example, aligned CNT fibers are attractive for use for continuous fiber reinforcement of aluminum metal matrix composites used in overhead transmission lines. The CNT materials, CNT-to-metal connectors, CNT connector pads, and assemblies described herein offer further advantages in these contexts, by addressing electrical transmission losses. The U.S. electric grid is estimated to lose roughly 6% of total generated power to transmission losses. The present disclosure provides materials and methods for mitigation of losses at the connector site as well as within the conductor, and could significantly reduce energy consumption.

### Definitions

Technical and scientific terms used herein have the meanings commonly understood by one of ordinary skill in the art to which the present invention pertains, unless otherwise defined. Any suitable materials and/or methods known to those of ordinary skill in the art can be utilized in carrying out the present invention in view of the guidance provided herein; however, specific materials and methods are described for illustrative purposes. Materials, reagents and the like to which reference is made in the following description and examples are obtainable from commercial sources, unless otherwise noted.

As used herein, the singular terms “a,” “an,” “the,” and “said” include plural referents unless the context clearly dictates otherwise. Reference to an object in the singular is not intended to mean “one and only one” unless explicitly so stated, but rather “one or more”.

As used herein, “about” when used with a numerical value means the numerical value stated as well as plus or minus 10% of the numerical value. For example, “about 10” should be understood as both “10” and “9-11”.

As used herein, the terms “e.g.,” “such as”, “for example”, “for an example”, “for another example”, “examples of”, “by way of example”, and “etc.” indicate that a list of one or more non-limiting example(s) precedes or follows; it is to be understood that other examples not listed are also within the scope of the present disclosure.

As used herein, a phrase in the form “A/B” or in the form “A and/or B” includes (A), (B), and (A and B); a phrase in the form “at least one of A, B, and C” includes (A), (B), (C), (A and B), (A and C), (B and C), and (A, B, and C).

As used herein, the terms “comprising,” “including,” and “containing” are used expansively to mean that the described compositions or methods include at least the stated elements, and may include other elements that are not specified. The phrase “consisting essentially of” is used to include those elements specifically recited and additional elements that do not materially affect the basic and novel characteristics of the claimed invention. For example, the CNT-to-metal assemblies described herein may include additional elements such as electrical insulation (e.g., to ensure the connector assembly is properly isolated from other connections) and/or dopants. In some embodiments, such elements (e.g., electrical insulation or dopants) do not materially affect the basic and novel characteristics of the claimed invention.

### CNT Materials

Described herein are CNT materials that can form good CNT-to-metal connections and exhibit good performance (e.g. good electrical performance) when connected to metals. CNT materials as described herein (such as CNT fibers and CNT films) can be made by methods disclosed in U.S. Pat. No. 11,111,146, which is incorporated by reference in its entirety. Other documents that described methods that can be used to prepare CNT materials as described herein include U.S. Patent Publication Nos. 2011/0110843, 2015/0298164, and 2017/0243668, each of which is incorporated by reference in its entirety. In some embodiments, CNT material as described herein is in the form of a CNT foam. A CNT foam can be made by methods known in the art, such as disclosed in U.S. Patent Publication No. 2014/0141224A1, which is incorporated by reference in its entirety. For example, a CNT foam may be manufactured by one or more or all of the following steps: preparing a CNT solution from raw CNT materials and a superacid to obtain a CNT solution and coagulating the CNT solution within a mold (e.g., a mold configured to hold the CNT solution in place during coagulation) to obtain a CNT foam. CNT materials that exhibit good performance (e.g., high electrical conductivity and/or high aspect ratio as described herein) can be produced when the constituent CNTs satisfy one or more or all of the following properties: they are aligned, p-type doped, and/or undamaged (e.g., the original length distribution of the CNTs is retained). Typically, raw (unprocessed) CNTs as obtained immediately post-synthesis are unaligned, semiconducting, and un-doped, and typically have a log-normal length distribution. As such, aligning CNTs, p-type doping semiconducting CNTs, and/or retaining the original length distribution can obtain CNT materials with good performance (e.g., high electrical conductivity and/or high aspect ratio as disclosed herein). Illustrative examples of such processes are disclosed in U.S. Pat. No. 11,111,146, and outlined below and discussed in more detail further below.

For example, aligning CNTs can be achieved through one or more or all of the following steps: cryogenic blending and/or mixing raw CNTs with a superacid to form a thermodynamically stable CNT-superacid fluid; extruding CNT-containing material (such as a CNT-superacid mixture) to obtain an extrudate; and/or coagulation (e.g., removing the solvent (e.g., the superacid)). While not wanting to be bound by theory, it is understood that superacids can protonate CNT molecules, thereby inducing a repulsive force between CNTs and causing CNT molecules to align as the concentration of CNTs in the solvent (e.g., the superacid) is increased due to excluded volume interactions. It also is believed that CNT liquid crystals can be formed by this process. Further, it is understood that in the extrusion step, shear and extensional flow fields can cause the liquid crystal domains to stretch and align in the flow direction; achieving additional alignment of the CNT molecules. Using a coagulation method for removing a solvent (e.g., the superacid) can enable fine control over the rate of solvent diffusion (e.g., diffusion of solvent out of the system) and the pace of coagulation, such as via selection of a coagulant in which the solvent (e.g., the superacid) is soluble but the CNTs are not. Fine tuning the pace of coagulation can improve alignment of the CNTs. For example, if the coagulation is too slow, the CNT molecules may become overly relaxed and lose their alignment post-extrusion. On the other hand, if the coagulation is too fast, rapid reactions between the solvent (e.g., the superacid) and the coagulant may cause a disruption in the aligned microstructure of the fluid. For example, the pace of coagulation may be controlled via the selection of the coagulant (e.g., acetone may coagulate relatively quickly while chloroform may coagulate more slowly) and/or by promoting exposure to “fresh” coagulant (to increase the pace), such as by a spray coagulation method as disclosed in U.S. Pat. No. 11,111,146.

Additionally or alternatively, p-type doping can be achieved via cryogenic blending and/or mixing of CNTs with a superacid solvent. Without being bound by theory, it is believed that superacids can p-type dope semiconducting CNTs. Accordingly, homogeneous blending and/or mixing of superacid solvent with CNTs can be effective in this regard.

Retaining the original length distribution of the CNTs can be achieved by conducting cryogenic blending and/or mixing of CNTs (e.g., with a superacid solvent) in a manner that reduces or minimizes shear forces (which may otherwise be applied in a regular mixing step to overcome diffusion-limited entry of solvent into raw CNT materials). Accordingly, by avoiding high shear forces, the CNTs are not irreversibly damaged by ultra-high shear forces they may otherwise be subjected to. For example, studies have shown that ultrasonication (e.g., ultrasonication applied during a mixing step) can damage (e.g., break) CNTs, such that the average length of the CNTs is reduced, likely due to high shear forces.

Accordingly, CNTs that are aligned, p-type doped, and undamaged (e.g., the original length distribution of the CNTs is retained) can be obtained as noted above. Without being bound by theory, it is believed that alignment can increase the mean free path of electrons travelling within the CNT material by reducing the number of inter-CNT junctions (where an electron would be forced to travel from one CNT to an adjacent CNT). Inter-CNT junction resistance is generally regarded as a major limiting factor towards translating the astonishing electrical conductivity of a single CNT to the macroscopic scale of a CNT material. Thus, alignment of the CNTs can achieve high electrical conductivity in the CNT material. Additionally, p doping also increases electrical conductivity. On the other hand, preventing damage (e.g., breakage) that preserves the length distribution achieves a high aspect ratio, which is generally believed to be relevant to mechanical toughness as well as electrical conductivity of a finished product.

In some aspects, the CNT materials described herein are included in a CNT component (e.g., a CNT component of a device, such as those mentioned above). In some aspects, the CNT materials described herein are included in a CNT connector pad as described herein.

In some embodiments, a CNT material as described herein comprises at least 90 wt %, at least 95 wt %, or at least 99 wt % CNTs. The CNTs may be any one or more selected from single-walled CNTs, double-walled CNTs, and multi-walled CNTs. The CNTs of the CNT material described herein may have one or more are all of the advantageous properties described herein below.

In some embodiments, the CNT material described herein has an electrical conductivity of at least 1 MS/m, at least 5 MS/m, or at least 10 MS/m. Additionally or alternatively, in some embodiments, the CNTs of the CNT material described herein have an average aspect ratio of at least 1000, at least 5000, or at least 10000. Additionally or alternatively, in some embodiments, the CNTs of the CNT material described herein have an average G/D ratio of at least 1, at least 10, or at least 100. In some embodiments, the CNTs of the CNT material described herein have an electrical conductivity of at least 1 MS/m, at least 5 MS/m, or at least 10 MS/m, an average aspect ratio of at least 1000, at least 5000, or at least 10000, and an average G/D ratio of at least 1, at least 10, or at least 100.

The CNT material described herein may or may not comprise non-sp2-hybridized carbon material. In some embodiments, the CNT material described herein comprises less than 20 wt %, less than 10 wt %, or less than 5 wt % of non-sp2-hybridized carbon material. In some embodiments, the CNT material described herein is substantially free of non-sp2-hybridized carbon material. In some embodiments, non-sp2-hybridized carbon material is absent from the CNT material. As used herein, term “substantially free of” indicates that the material (e.g., non-sp2-hybridized carbon material) is below the TGA (thermal gravimetric analysis) detectable limit, while the term “absent from” indicates that the material is below the EELS (electron energy loss spectroscopy) detectable limit.

The CNT material described herein may or may not comprise impurities such as metallic particle impurities. In some embodiments, the CNT material described herein comprises less than 10 wt %, less than 5 wt %, or less than 2 wt % of metallic particle impurities. In some embodiments, the CNT material described herein is substantially free of metallic particle impurities. In some embodiments, metallic particle impurities are absent from the CNT material. Without being bound by theory, it is believed that in certain applications such as AC signal transmission applications, the presence of ferromagnetic compounds (e.g., Fe) can introduce distortions to the signal such as passive intermodulation (PIM); thus, it can be advantageous if the metal content in the CNT material (e.g., due to leftover metal catalyst particles in CNT material used as a CNT component or CNT connector pad as described herein) is negligible in such applications. Additionally or alternatively, in certain applications, such as RF applications, the presence of ferromagnetic compounds (e.g., Fc) may introduce additional loss mechanisms; thus it can be advantageous if the metal content in the CNT material is negligible for such applications as well.

The CNT material may have any suitable density for its intended use (e.g., for the type of device and/or type of use). In some embodiments, the CNT material has a density of at least 1 g/cm³, at least 1.2 g/cm³, or at least 1.4 g/cm³.

As noted above, a CNT material as used herein may exhibit one or more or all of the properties described herein (including the properties described above).

When the CNT material is part of a CNT component (e.g., a CNT component comprising or comprised of the CNT material), the form of a CNT component can vary depending on the particular application. For example, the CNT component may be a CNT coating, a CNT film, a CNT foam, or a CNT fiber.

Without being bound by theory, it is believed selecting and using CNT materials that exhibit one or more or all of the properties described above may address and/or overcome one or more of the problems discussed above that arise when connecting a CNT component to a metal component. For example, using CNT materials with a high density may result in fewer undesired void spaces; using CNT materials with a high conductivity may result in reduced contact resistance; using CNT materials with a high aspect ratio may result in better fatigue resistance for the CNT material, making the connector site less susceptible to damage in challenging use cases (e.g., those involving chemically aggressive environments and/or involving mechanical/thermal cycling); using CNT materials with a high G/D ratio may improve the CNT materials' chemical and thermal resistance, making the connector site less susceptible to damage in challenging use cases. Using CNT materials with one or both of a high G/D ratio and high aspect ratio may improve electrical conductivity.

### CNT Connector Pads

CNT materials as described above may be used to form a CNT connector pad, such as a connector pad that can serve as an interface between a CNT component and a metal component, or as an interface between a CNT component and another CNT-to-metal connector. Without being bound by theory, it is believed that mechanical properties of the CNT connector pad as described herein may permit it to be mechanically compressed without being damaged; additionally, if high electrical conductivity enables minimum losses at the interfaces with the CNT component and metal component.

As discussed in more detail below, also provided herein are CNT-to-metal assemblies comprising a CNT component and a metal component, connected via a CNT connector pad used alone or with another CNT-to-metal connector. The present disclosure includes CNT connector pads as such, as well as CNT connector pads present in CNT-to-metal assemblies.

A CNT connector pad as described herein comprises CNT material as described herein, e.g., having one or more or all of the advantageous properties described above. As a non-limiting example, a CNT connector pad as described herein may be prepared from CNT material comprised of CNTs that have an electrical conductivity of at least 1 MS/m, at least 5 MS/m, or at least 10 MS/m, and an average aspect ratio of at least 1000, at least 5000, or at least 10000, and wherein the CNT material has an average G/D ratio of at least 1, at least 10, or at least 100. Additionally or alternatively, the CNT material of the CNT connector pad may comprise less than 20 wt %, less than 10 wt %, or less than 5 wt % of non-sp2-hybridized carbon material. Additionally or alternatively, the CNT material of the CNT connector pad may comprise less than 10 wt %, less than 5 wt %, or less than 2 wt % of metallic particle impurities. Additionally or alternatively, the CNT material of the CNT connector pad may have a density of at least 1 g/cm³, at least 1.2 g/cm³, or at least 1.4 g/cm³. The CNT connector pad may comprise at least 90 wt %, at least 95 wt %, or at least 99 wt % CNTs.

The form of a CNT connector pad as described herein is not particularly limited. In general, a CNT connector pad will be of a form or configuration that can be disposed on, formed on, wrapped (or tied) around, surround, or coat a metal component (e.g., a metal component of an assembly). In some embodiments, a CNT connector pad as described herein is in the form of a pre-formed film or foam of CNT material. In some embodiments, a CNT connector pad as described herein is a film or foam or coating of CNT material that is formed directly on a surface of a component of the assembly (e.g., a film or foam or coating formed directly on a surface of a metal component of the assembly). In some embodiments, a CNT connector pad as described herein is formed from CNT fibers. In some aspects of any of these embodiments, a CNT connector pad as described herein is a separate structure from the CNT component of the assembly. In other aspects of any of these embodiments, a CNT connector pad as described herein is a region of the CNT component of the assembly.

In some embodiments, the CNT connector pad is able to conform to a non-planar surface (e.g., a non-planar surface of a metal component of an assembly), such as by having sufficient flexibility to conform to a non-planar surface and/or having a shape complementary to a non-planar surface.

A CNT connector pad as described herein can be made in any desired shape. For example, a CNT connector pad may be square, circular, or any centrosymmetric shape suitable for through-type connectors. A CNT connector pad may be rectangular, semi-circular, or symmetric about a middle axis for end-launch-type connectors. A CNT connector pad may comprise a concentric rectangular trace, spiral, or be arranged in an orientation selected to optimize resonance with an adjacent metallic resonant circuit for inductive-type connectors.

A CNT connector pad may be prepared as a pre-formed film or foam for wrapping (or tying, including tying a knot) around a metal component (e.g., in the form of a “tape”). A CNT connector pad may be formed from or in the form of one or more fibers, e.g., one or more fibers which can be wrapped (or tied) around a metal component. A CNT connector pad may be in the form of a pre-formed film or foam with a generally cylindrical (capped or uncapped) shape, for enveloping a metal component (optionally for use with a transfer sleeve as described in more detail below). A CNT connector pad may be a film or foam or coating formed on the surface of a metal component from a fluid phase (as described in more detail below).

In some embodiments, the CNT connector pad is comprised of a single layer of CNT material as described herein. In some embodiments, such a single-layered CNT connector pad has a thickness of from about 1 μm to about 10 μm, including from 1 μm to 10 μm, such as about 1 μm, about 2 μm, about 3 μm, about 4 μm, about 5 μm, about 6 μm, about 7 μm, about 8 μm, about 9 μm, or about 10 μm, or any value therebetween. In some embodiments, a single-layered CNT connector pad is formed by wrapping (or tying) a CNT fiber or pre-formed CNT film or foam around the metal component. In some embodiments, a single-layered CNT connector pad is formed by applying a pre-formed film with a generally cylindrical (capped or uncapped) shape for enveloping a metal component (as described in more detail below). In some embodiments, a single-layered CNT connector pad is formed on the surface of a metal component from a fluid phase (as described in more detail below).

In some embodiments, the CNT connector pad comprises a plurality of layers of CNT material as described herein (e.g., is a multi-layered CNT connector pad). In some embodiments, a multi-layered CNT connector pad has a thickness of from about 1 μm to about 0.5 mm, including from 1 μm to 0.5 mm, such as about 1 μm, about 10 μm, bout 50 μm, about 0.1 mm, about 0.2 mm, about 0.3 mm, about 0.4 mm, or about 0.5 mm, or any value therebetween. In some embodiments, a multi-layered CNT connector pad is formed by wrapping (or tying) a pre-formed CNT film or foam or one or more CNT fiber(s) around a metal component until multiple layers are formed. In some embodiments, a multi-layered CNT connector pad is formed by applying multiple layers of separate pre-formed CNT films or foams onto a surface of a metal component to form multiple layers. In some embodiments, a multi-layered CNT connector pad is formed in situ from a fluid phase, where the layers are formed directly on a surface of a metal component from a fluid phase.

In some embodiments wherein the CNT connector pad comprises a plurality of layers of CNT material, the plurality of layers comprises an outer layer of CNT material and one or more intermediate layers of CNT material, where the “outer” layer is closer to the CNT component and further from the metal component, and the “intermediate” layers are closer to/disposed on the metal component. In some embodiments, one or more of the intermediate layers may be provided with a thin film comprising a conductive material, such as a metal or other conductive material. In accordance with such embodiments, the film may be provided by any suitable method, such as being sputter-coated, electroplated, vapor deposited, etc. In some embodiments, the film comprises one or more metals selected from Cu, In, Ni, Ag, Au, Sn, Al, Zn, Pt, Pd, Pb, Mo, Mg, Rh, and W. As used herein, a “thin” film may have a thickness in a range from 1 nm to 100 μm (0.1 mm). Depending on the application and environmental conditions, some metals maybe better suited than others to provide a high surface area metallic interface for electrical connections to CNT materials.

Another property that can be selected and controlled to achieve desired properties is CNT alignment. In some contexts, CNT alignment is a preferred structure to achieve certain high-performance properties. However, the introduction of an anisotropic conductivity at the connector site may have detrimental effects on connector performance in certain applications. In that context, it can be advantageous to use a CNT connector pad comprising a single layer of aligned or unaligned CNT material as described herein or a plurality of layers of aligned CNT material as described herein, wherein the layers have a different orientation relative to each other. For example, in some embodiments, in a CNT connector pad comprising a plurality of layers of CNT material as described herein, the CNT connector pad may comprise a first layer of CNT material (e.g., a CNT material as described herein) and a second layer of CNT material (e.g., a CNT material as described herein), wherein the first and second layers are arranged in a different orientation relative to each other. For example, in a CNT connector pad comprised of five layers, the layers can be aligned in approximate 36-degree increments, to cover 180 degrees altogether. As another example, the orientation of CNT connector pad layer alignment can be selected and designed to obtain different antenna properties. For example, perpendicular orientation of CNT connector pad layer(s) with respect to a direction of current transport can produce a more wideband (low-Q) resonance, while parallel orientation with respect to a direction of current transport can produce a more narrow (high-Q) resonance. In these embodiments, the CNT material of each layer may be a CNT material as described herein, optionally wherein each layer is comprised of the same CNT material or wherein one or more layers are comprised of a different CNT material, each having a structure and properties as described herein.

As noted above, a CNT connector pad as described herein is advantageously used as an interface for a CNT-to-metal assembly, e.g., to connect a CNT component to a metal component. Additionally or alternatively, as also noted above, a CNT connector pad as described herein is advantageously used as an interface in a CNT-to-metal assembly, e.g., to connect a CNT component to a metal component via another CNT-to-metal connector, such as CNT-to-metal connectors that are known in the field. Unless otherwise stated, in any embodiments and any configurations described herein, in any given assembly, the CNT material of the connector pad may be the same as or different from the CNT material of the CNT component.

In the context of CNT components that are CNT coatings, attaching a typical CNT-to-metal connector to a thin layer of a soft CNT component may damage the CNT component, particularly during thermal and mechanical cycling. In contrast, a CNT connector pad as described herein can provide a durable, conformal, high conductivity interface (between a CNT component and a metal component or between a CNT component and another CNT-to-metal connector) that can dissipate both mechanical and thermal energy from the connector and the environment in order to protect the underlying thin CNT coating, while ensuring a stable electrical connection.

In the context of CNT components that are CNT films or foams, where the film or foam area is limited, a CNT connector pad as described herein can be formed from the same material as the CNT film or foam (e.g., can be part of the same structure as the CNT component, e.g., can be a region of the CNT component) or can be deposited on top of the CNT film or foam as a reinforcement.

In the context of CNT components that are CNT fibers, comprised of thin CNT filaments that may not offer a large area for interfacing with a connector, a CNT connector pad as described herein can be connected to the end of the fiber, to provide a larger area, durable, and low contact resistance site to facilitate interfacing with a metal or another CNT-to-metal connector.

Use of a connector pad and/or the surface preparation and bonding methods disclosed herein can enhance the connection, such as by reducing surface roughness at the connection site, reducing entrained void spaces, increasing contact area, and providing good contact resistance, as compared to conventional CNT-to-metal connections.

### Connected Assemblies

In another aspect, the present disclosure provides assemblies (e.g., CNT-to-metal assemblies) comprising a carbon nanotube (CNT) component connected to a metal component. The assemblies (e.g., CNT-to-metal assemblies) described herein may exhibit one or more or all of the following advantageous properties. For example, the assemblies described herein (e.g., CNT-to-metal assemblies) may exhibit advantageous signal attenuation. In some embodiments, the assemblies described herein may have a signal attenuation of 20 dB to 30 dB. In some embodiments, the assemblies described herein may have a signal attenuation of 10 dB to 20 dB. In some embodiments, the assemblies described herein may have a signal attenuation of 5 dB to 10 dB. Additionally or alternatively, the assemblies described herein may exhibit an advantageous signal to noise ratio (e.g., a signal to noise ratio of 2:1 to 100:1, or greater). In some embodiments, the assemblies described herein may have a signal to noise ratio of from 2:1 to 5:1. In some embodiments, the assemblies described herein may have a signal to noise ratio of from 5:1 to 20:1. In some embodiments, the assemblies described herein may have a signal to noise ratio of from 20:1 to 100:1. Additionally or alternatively, the assemblies described herein may have advantageous phase shift properties relative to the original signal going into the assembly). In some embodiments, the assemblies described herein may have a phase shift of less than pi/12 rad. In some embodiments, the assemblies described herein may have a phase shift of less than pi/24 rad. In some embodiments, the assemblies described herein may have a phase shift of less than pi/96 rad. Additionally or alternatively, the assemblies described herein may exhibit advantageous temperature difference properties relative to the steady state temperature of the metal component. In some embodiments the assemblies described herein may have a temperature difference of less than 25° C., in some embodiments the assemblies described herein may have a temperature difference of less than 15° C., in some embodiments, the assemblies described herein may have a temperature difference of less than 5° C., all relative to the steady state temperature of the metal component.

In this context, a CNT component of the assemblies described herein (e.g., CNT-to-metal assemblies) comprises or is comprised of a CNT material as described herein, e.g., having one or more or all of the advantageous properties described herein.

Illustrative CNT components include but are not limited to display electrodes, touch screen electrodes, energy harvesting electrodes, solar cell electrodes, battery electrodes, static-dissipative elements, grounding elements, resistive heating elements, strain sensing elements, chemical sensor elements, the radiating element of an antenna, the ground plane of an antenna, the outer shield of a coaxial cable, the inner conductor of a coaxial cable, smart coatings for in-situ monitoring of abrasion, other resistive elements for sensors, other capacitive elements for sensors, other inductive elements for sensors, biosensing elements for muscular or neural activity, muscular and/or neural stimulation electrodes, DC power cables and transmission lines, AC power cables and transmission lines, field emitters, transformer coils, DC motor coils, electronic textiles, transistors, conductors, capacitors, or inductors.

Illustrative metal components include but are not limited to a metal matrix, metal wires, metal cables, ring terminals, circuit board terminals, quick-disconnect terminals, spade terminals, hook terminals, snap plug terminals, battery terminals, battery terminal clamps, battery springs, grounding blocks, butt splices, wire ferrules, terminal blocks, compression lugs, set screw lugs, BNC (Bayonet Neill-Concelman) connectors, TNC (Threaded Neill-Concelman) connectors, RCA (Radio Corporation of America) connectors, SMA (SubMiniature version A) connectors, SMC (SubMiniature version C) connectors, FFC (Flat Flexible Cable) connectors, FPC (Flexible Printed Circuit) connectors, DIN (Deutsches Institut fur Normung) connectors, and F-type connectors.

As a non-limiting example, the CNT component may comprise or be comprised of a CNT material that comprises CNTs that have an electrical conductivity of at least 1 MS/m, at least 5 MS/m, or at least 10 MS/m, and an average aspect ratio of at least 1000, at least 5000, or at least 10000, and wherein the CNT material has an average G/D ratio of at least 1, at least 10, or at least 100. Additionally or alternatively, the CNT material of the CNT component may comprise less than 20 wt %, less than 10 wt %, or less than 5 wt % of non-sp2-hybridized carbon material. Additionally or alternatively, the CNT material of the CNT component may comprise less than 10 wt %, less than 5 wt %, or less than 2 wt % of metallic particle impurities. Additionally or alternatively, the CNT material of the CNT component may have a density of at least 1 g/cm³, at least 1.2 g/cm³, or at least 1.4 g/cm³. The CNT material of the CNT component may comprise at least 90 wt %, at least 95 wt %, or at least 99 wt % CNTs.

In some embodiments, the metal component of an assembly as described herein may be or comprise a metal matrix or any metal connector, such as a wire (e.g., solid core or braided wire), metal cable, plug, lug, ferrule, wire nuts, spade terminal, hook terminal, ring terminal, block terminal, pin terminal, etc. The metal component may comprise or be comprised of any metal, such as one or more metals selected from Cu, In, Ni, Ag, Au, Sn, Al, Zn, Pt, Pd, Pb, Mo, Mg, Rh, and W.

In some embodiments, the CNT component is connected to the metal component through a CNT-to-metal connector as described herein. In some embodiments, a connector pad as described herein serves as the CNT-to-metal connector. In other embodiments, the CNT-to-metal connector is a conventional CNT-to-metal connector (e.g., a CNT-to-metal connector known in the field). In other embodiments, the CNT-to-metal connector comprises a CNT connector pad as described herein and another CNT-to-metal connector (such as a CNT-to-metal connector known in the field).

In some embodiments, the CNT-to-metal connector component comprises a material selected from graphene, metals, and metal-containing epoxies. In some embodiments, the graphene is dispersed in a slurry, paste, or suspension. In some embodiments, the metal is one or more selected from Cu, In, Ni, Ag, Au, Sn, Al, Zn, Pt, Pd, Pb, Mo, Mg, Rh, and W. In some embodiments, the metal-containing epoxy is a silver-containing epoxy.

As noted above, in some embodiments, the CNT-to-metal connector described herein further comprises a CNT connector pad (e.g., a CNT connector pad as described herein). The surface of the CNT connector pad may be connected to a standard metal connector through any suitable means, e.g., a reactive foil containing an Al/Ni/Sn solder (or other metal compounds), and/or by applying one or more of pressure, current (e.g., for resistive heating) and heat to the CNT/connector/foil assembly, e.g., at the interface.

In some embodiments, the CNT-to-metal connector described herein does not comprise a CNT connector pad as described herein.

Thus, in some embodiments, provided herein is an assembly comprising a carbon nanotube (CNT) component connected to a metal component, wherein the CNT component is connected to the metal component through a CNT-to-metal connector that comprises a material selected from graphene, metals, and metal-containing epoxies. In some embodiments, provided herein is an assembly comprising a carbon nanotube (CNT) component connected to a metal component, wherein the CNT component is connected to the metal component through a CNT-to-metal connector that comprises (a) a material selected from graphene, metals, and metal-containing epoxies; and (b) a CNT connector pad (e.g., a CNT connector pad as described herein). In some embodiments, provided herein is an assembly comprising a carbon nanotube (CNT) component connected to a metal component, wherein the CNT component is connected to the metal component through a CNT connector pad (e.g., a CNT connector pad as described herein).

In accordance with any of these embodiments, the junction (interface) between the CNT material (of the CNT component or CNT connector pad) and CNT-to-metal connector or metal may be wrapped (or tied) with a CNT fiber. In some embodiments, the CNT fiber is knotted for added durability. In some embodiments, the CNT fiber is a CNT material as described herein, e.g., has one or more or all of the advantageous properties described herein.

Additionally or alternatively, in accordance with any of the assembly embodiments, the surface of the CNT material (of the CNT component or CNT connector pad) may be provided with a thin film comprising a conductive material, such as a metal or other conductive material. In accordance with such embodiments, the film may be provided by any suitable method, such as being electroplated, sputter-coated, vapor deposited, etc. In some embodiments, the film comprises one or more metals selected from Cu, In, Ni, Ag, Au, Sn, Al, Zn, Pt, Pd, Pb, Mo, Mg, Rh, and W. As used herein, a “thin” film may have a thickness in a range from 1 nm to 100 μm (0.1 mm). Accordingly, the surface described herein (e.g., the surface of the CNT material (of the CNT component or CNT connector pad)) can be more wettable for subsequent soldering, brazing, fusing or welding. The wetted surface may then be soldered, brazed, welded, or fused to form a connection with a metal connector through use of an appropriate metal filler compound. Whereas metals do not normally wet CNTs readily, e.g., given their irregular surface topology, as illustrated in the examples below, the present inventors have found that good metal coverage can be achieved with CNT materials as described herein.

Ni metal can be of particular interest in cases where the flexibility of the CNT material is an issue at the connector site. Without being bound by theory, it is believed that Ni can add significant rigidity to the CNT material even when used in small quantities, because Ni is a hard metal. Additionally, Ni is corrosion resistant and stable at high temperatures, making it capable of stabilizing dopants, such as acidic dopants from solution processing in superacids. Thus, in particular embodiments of any of the assembly embodiments, the surface of the CNT material (of the CNT component or CNT connector pad) may be provided with a thin film comprising Ni.

In metal also can be of particular interest in cases where its low melting point is advantageous, such as to facility manufacture. Thus, in particular embodiments of any of the assembly embodiments, the surface of the CNT material (of the CNT component or CNT connector pad) may be provided with a thin film comprising In. In other particular embodiments of any of the assembly embodiments, the surface of the CNT material (of the CNT component or CNT connector pad) may be provided with a thin film comprising Cu.

Additionally or alternatively, in accordance with any of the assembly embodiments, the surface of the CNT material (of the CNT component or CNT connector pad) may be coated with a conductive compound, such as a metal-filled epoxy, such as a silver epoxy, other solder paste, conductive polymer, or metal-filled polymer, to facilitate electrical contact with a mechanical connection, such as a crimp or spring-loaded connector.

### Methods of Making Assemblies

In another aspect, provided herein are methods of making an assembly (e.g., a CNT-to-metal assembly as described herein).

In some embodiments, the assembly is prepared by directly attaching a CNT material (e.g., the CNT material of a CNT component) to a metal component. In some embodiments, the assembly comprises a CNT connector pad as described herein. Thus, a method for preparing an assembly as described herein may comprise providing a surface of a CNT material (e.g., the CNT material of a CNT component) with a CNT connector pad as disclosed herein. Once a CNT connector pad is provided on a CNT material (e.g., the CNT material of a CNT component), that sub-assembly may be connected to a metal component. Additionally, or alternatively, a method for preparing an assembly as described herein may comprise providing a surface of a metal component with a CNT connector pad as disclosed herein. Once a CNT connector pad is provided on a metal component, that sub-assembly may be connected to a CNT material (e.g., the CNT material of a CNT component). More specific embodiments are described in more detail below.

### Connecting a CNT Connector Pad to a CNT Component

In some embodiments, a method of making an assembly as described herein may comprise connecting a CNT connector pad (e.g., a CNT connector pad as described herein) to a CNT component (e.g., a CNT component as described herein), wherein each of the CNT connector pad and the CNT component independently comprise or are comprised of a CNT material as described herein (e.g., having one or more or all of the advantageous properties described herein).

In some embodiments, a method of connecting a CNT connector pad to a CNT component comprises contacting the CNT component and the CNT connector pad at an interface, optionally further comprising crimping and/or clamping the CNT component and the CNT connector pad together.

In some embodiments, a method of connecting a CNT connector pad to a CNT component comprises evaporating a solvent at the interface to connect the CNT component to the CNT connector pad via capillary action. In some embodiments, the solvent is one or more selected from water, acetone, methyl ethyl ketone, diethyl ether, chloroform, n-hexane, ethanol, ethylene glycol, xylene, toluene, THF (tetrahydrofuran), NMP (N-Methyl-2-pyrrolidone), and HFEs (hydrofluoroethers). In some embodiments, one or more of pressure, current (e.g., for resistive heating) and heat may be utilized at the interface to assist in forming a connection between the CNT component and the CNT connector pad.

In some embodiments, a method of connecting a CNT connector pad to a CNT component comprises solvent-welding the CNT connector pad to the CNT component using an acid, e.g., a strong acid or superacid. In some embodiments, the strong acid or superacid is one or more selected from Bronsted strong acids or superacids, Lewis strong acids or superacids, conjugate Bronsted-Lewis strong acids or superacids, and combinations of any two or more thereof. In some embodiments, the strong acid or superacid is one or more selected from sulfuric acid, perchloric acid, chlorosulfonic acid, fluorosulfonic acid, trifluoromethane sulfonic acid, perfluoroalkane sulfonic acids, antimony pentafluoride, arsenic pentafluoride, oleums, polyphosphoric acid-oleum mixtures, tetra (hydrogen sulfate) boric acid-sulfuric acid, fluorosulfuric acid-antimony pentafluoride, fluorosulfuric acid-SO₃, fluoro sulfuric acid-arsenic pentafluoride, fluorosulfonic acid, fluorosulfonic acid-hydrogen fluorideantimony pentafluoride, fluorosulfonic acid-antimony pentafluoride-sulfur trioxide, fluoroantimonic acid, tetrafluoroboric acid, triflic acid, and combination of any two or more thereof. In some embodiments, the strong acid or superacid is provided in a solution containing CNTs (of the CNT component) in an amount up to about 20% by weight, including up to 20% by weight, such as up to 15% by weight, or up to 10% by weight.

In some embodiments, a method of connecting a CNT connector pad to a CNT component comprises mechanically attaching the CNT connector pad to the CNT component, such as threading CNT fibers through the CNT connector pad and the CNT component. In some embodiments, the CNT fiber is a CNT material as described herein, e.g., has one or more or all of the advantageous properties described herein.

### Connecting a CNT Connector Pad or a CNT Component to A Metal Component

In some embodiments, a method of making an assembly as described herein comprises connecting a CNT component (e.g., a CNT component as described herein) or CNT connector pad (e.g., a CNT connector pad as described herein) to a metal component (e.g., a metal component as described herein). As discussed in more detail below, in some embodiments a surface of the metal component is coated with a CNT film or foam (e.g., coated as a fluid phase) to provide a CNT connector pad on the metal component. Additionally or alternatively, as also discussed in more detail below, in some embodiments a surface of the metal component is mechanically attached to a pre-formed CNT connector pad, such as a solid CNT film or CNT foam. Additionally or alternatively, as also discussed in more detail below, in some embodiments a surface of the metal component is mechanically attached to a pre-formed CNT connector pad, such as by wrapping (or tying) with a pre-formed CNT film or foam or CNT fiber.

In some embodiments, a method of making an assembly as described herein comprises directly connecting a CNT component to a metal component (e.g., without a CNT connector pad). Such a method may comprise contacting (i) CNT material of the CNT component and (ii) the metal component at an interface to form a junction of the assembly. In some embodiments, the method may comprise crimping and/or clamping (i) with (ii) to form a junction of the assembly. In some embodiments, the method may comprise one or more or all of the following steps: wrapping (or tying) the junction with a CNT fiber or film or foam; electroplating a surface of the CNT material of the CNT component with a metal (e.g., a metal comprises one or more selected from Cu, In, Ni, Ag, Au, Sn, Al, Zn, Pt, Pd, Pb, Mo, Mg, Rh, and W); sputter-coating a surface of the CNT material of the CNT component with a metal (e.g., a metal comprises one or more selected from Cu, In, Ni, Ag, Au, Sn, Al, Zn, Pt, Pd, Pb, Mo, Mg, Rh, and W); wetting a surface of the CNT material of the CNT component prior to a soldering or brazing step; soldering or brazing the CNT material of the CNT component to the metal component; providing a conductive, metal-filled epoxy at the interface; and applying a reactive foil comprising a metal solder with one or more selected from pressure, current and heat at the interface. In some embodiments, the method may comprise potting, heat shrinking, or molding the assembly obtained from the aforementioned steps.

In other embodiments, a method of making an assembly as described herein employs a CNT connector pad as described herein. In such embodiments, the method may comprise connecting a CNT connector pad (optionally already connected to a CNT component) to a metal component using methodologies similar to those described above for directly connecting a CNT component to a metal component. For example, the method may comprise contacting (i) CNT material of a CNT connector pad (optionally already connected to a CNT component) and (ii) the metal component at an interface to form a junction of the assembly. In some embodiments, the method may comprise one or more or all of the following steps: wrapping (or tying) the junction with a CNT fiber or film or foam; electroplating a surface of the CNT material of the CNT connector pad with a metal (e.g., a metal comprises one or more selected from Cu, In, Ni, Ag, Au, Sn, Al, Zn, Pt, Pd, Pb, Mo, Mg, Rh, and W); sputter-coating a surface of the CNT material of the CNT connector pad with a metal (e.g., a metal comprises one or more selected from Cu, In, Ni, Ag, Au, Sn, Al, Zn, Pt, Pd, Pb, Mo, Mg, Rh, and W); wetting a surface of the CNT material of the CNT connector pad prior to a soldering or brazing step; soldering or brazing the CNT material of the CNT connector pad to the metal component; providing a conductive, metal-filled epoxy at the interface; and applying a reactive foil comprising a metal solder with one or more selected from pressure, current and heat at the interface. In some embodiments, the method may comprise potting, heat shrinking, or molding the assembly obtained from the aforementioned steps.

As noted above, in some embodiments, a CNT connector pad is in the form of a pre-formed CNT film or foam or CNT fiber. In such embodiments, the method may comprise contacting the pre-formed CNT film or foam or CNT fiber and the metal component at an interface to form a junction as described above, and, optionally performing one or more or all of the additional steps outlined above. Additionally or alternatively, the method may comprise wrapping (or tying, including tying a knot) a metal component with the pre-formed CNT film or foam or CNT fiber. Additionally or alternatively, the method may comprise inserting a metal component into a pre-formed CNT film or foam having a generally cylindrical (capped or uncapped) shape (optionally using a transfer sleeve as discussed below). Any such embodiments may optionally further comprise performing one or more or all of the additional steps outlined above. In some embodiments, wrapping (or tying) may be effected by dispensing the pre-formed CNT film or foam or CNT fiber onto the metal component while the metal component is spinning. In any embodiments, the pre-formed CNT film or foam or CNT fiber can be applied to achieve a single layer CNT connector pad or a multi-layered CNT connector pad, as described above, to achieve any CNT connector pad embodiments described above.

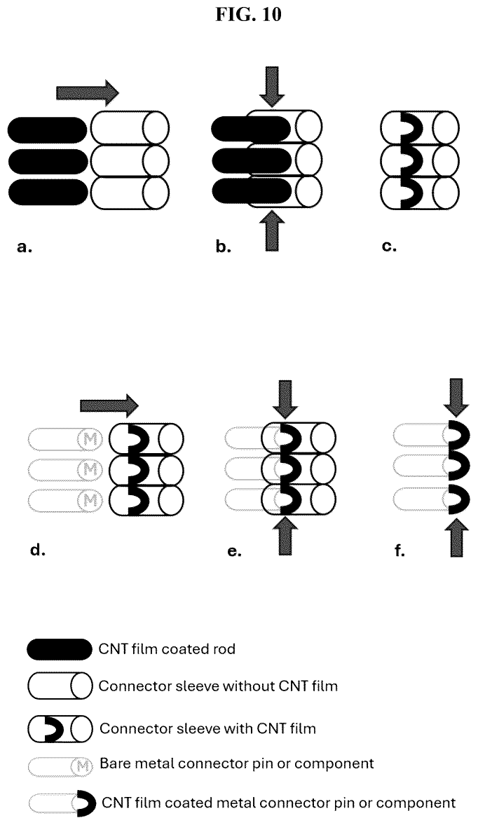

As noted above, in some embodiments the method may use a transfer sleeve to provide the metal component with a CNT connector pad prepared in the form of a pre-formed CNT film or CNT foam that has a generally cylindrical (capped or uncapped) shape, as illustrated in FIG. 10. For use in such embodiments, a transfer sleeve has a generally cylindrical and is sized and shaped to mate with the metal component such that the transfer sleeve can be placed around the metal component and/or the metal component can be inserted in the transfer sleeve for transfer of the CNT connector pad from the transfer sleeve to the metal component in accordance with the method. To facilitate such transfer, the internal dimensions of the transfer sleeve may be designed to provide a “tight fit” with the metal component. Typically the transfer sleeve will have a length correlated with the dimensions of the pre-formed CNT film or foam being transferred, such as being at least as long as the corresponding dimension of the pre-formed CNT film or foam being transferred. Advantageously, a transfer sleeve as described herein is made of a material with a low surface energy and low surface area to facilitate transfer. Additionally or alternatively, a transfer sleeve as described herein may be made of a soft material (e.g., a material that can be sufficiently deformed without irreversible damage during a transferring step). For example, a transfer sleeve as described herein may be made of one or more materials selected from high density polyethylene (HDPE), polypropylene (PP), fluorinated ethylene propylene (FEP), perfluoroalkoxy alkanes (PFA), ethylene tetrafluoroethylene (ETFE), and polytetrafluoroethylene (PTFE). In some embodiments, the transfer sleeve is a single-use sleeve. In some embodiments, the transfer sleeve is a multi-use sleeve. For example, a transfer sleeve may be used for up to 10,000 transfer cycles.

As illustrated in FIG. 10, the method generally comprises transferring a pre-formed CNT film or foam (CNT connector pad) from the interior of a transfer sleeve to the surface of a metal component (see FIG. 10, panels c-f). In some embodiments, the method may first comprise transferring the pre-formed CNT film or foam from a support (illustrated as a rod in FIG. panels a-b) to the interior of the transfer sleeve, such as by a process that comprises compressing the sleeve onto/around a support carrying the pre-formed CNT film or foam and, optionally, wetting (e.g., spraying with water), to obtain a transfer sleeve loaded with the pre-formed CNT film or foam (see FIG. 10, panels a-c). Alternatively, a transfer sleeve may be loaded with a CNT film or CNT foam by preparing the CNT film or CNT foam in situ inside the transfer sleeve, by forming the CNT film or CNT foam directly on interior surfaces of the transfer sleeve from a fluid phase, such as by using a process as generally described below for forming a CNT film directly on a metal surface.

To transfer the pre-formed CNT film or foam from the transfer sleeve to the metal component, the loaded transfer sleeve may be placed around the metal component and/or the metal component may be inserted in the transfer sleeve, followed by compressing the sleeve onto/around the metal component and, optionally, wetting (e.g., spraying with water), to transfer the pre-formed CNT film or foam to the metal component (see FIG. 10, panels d-c). After the metal component (now provided with the CNT film or foam CNT connector pad) is removed from the transfer sleeve, the method may further comprise one or more additional steps to further connect the CNT connector pad to the metal component as discussed below, such as one or more of applying further compression, evaporating a solvent (such as acetone) to promote densification via capillary action, and applying heat or a current (e.g., for resistive heating) (see FIG. 10, panel f).

The nature of the support is not critical, but it should be of appropriate dimensions to carry the pre-formed CNT film (the CNT connector pad) and be inserted into the transfer sleeve, and so generally may have the same cross-section dimensions as the metal component and a length at least as long or longer than the pre-formed CNT film, and, optionally, longer than the transfer sleeve. The support typically will comprise a suitable material for carrying and transferring the pre-formed CNT film (the CNT connector pad), such as polytetrafluoroethylene (PTFE), titanium, hastelloy, fluorinated ethylene propylene (FEP), etc.

In accordance with these embodiments, the pre-formed CNT film or CNT foam (the CNT connector pad) may be prepared by any suitable method that will result in a pre-formed CNT film or CNT foam suitable for use as a CNT connector pad as described herein being disposed on the support in a state that it can be transferred from the solid support to the transfer sleeve as described above. For example, in some embodiments, a pre-formed CNT film or CNT foam (e.g., the pre-formed CNT film or CNT foam to be transferred to the transfer sleeve) is disposed on the support by wrapping a CNT film or CNT foam or one or more CNT fibers around the support. Additionally or alternatively, in some embodiments, a pre-formed CNT film or CNT foam (e.g., the pre-formed CNT film or CNT foam to be transferred to the transfer sleeve) is formed directly on the surface of a solid support from a fluid phase (as described in more detail below). Alternatively, in some embodiments, a pre-formed CNT film or CNT foam (e.g., the pre-formed CNT film or CNT foam to be transferred via the transfer sleeve) is formed directly in the transfer sleeve (e.g., is formed directly on interior surfaces of the transfer sleeve) from a fluid phase, such as by using a process as generally described below for forming a CNT film directly on a metal surface.

As noted above, in other embodiments, a CNT connector pad (e.g., comprised of a CNT film or foam as described herein) is formed directly on the surface of a metal component from a fluid phase. Such a method may comprise one or more or all of following steps: preparing a CNT fluid; dip-coating a metal component with the CNT fluid; withdrawing the metal component from the CNT fluid; coagulating the coated CNT fluid (i.e., the CNT fluid coated on the surface of the metal component); and washing the CNT-coated metal component.

The CNT fluid may be prepared as described in U.S. Pat. No. 11,111,146, which is incorporated herein by reference in its entirety. For example, the CNT fluid may be prepared by one or more or all of the following steps: solid state blending of a carbon nanotube starting material (e.g., raw CNTs, such as unprocessed CNTs in powder form) with solid solvent particles of a carbon nanotube solvent followed by solvent activation (e.g., liquidating the solid solvent particles, such as by heating) to obtain a carbon nanotube solvent), and mixing to obtain a CNT fluid. Alternatively, the CNT fluid may be prepared by one or more or all of the following steps: blending carbon nanotube starting material with a carbon nanotube solvent precursor followed by reacting the solvent precursor with a solvent activation agent to obtain a carbon nanotube solvent, and mixing to obtain a CNT fluid. The CNT fluid can be dispensed onto a surface of a metal component, e.g., by extrusion, optionally followed by a solidifying step. In some embodiments, the solidifying step comprises exposure to an infrared radiation source, optionally wherein the infrared radiation is at a wavelength that reduces absorption of radiation by the nanotube solvent relative to absorption of radiation by the carbon nanotubes. Additionally or alternatively, in some embodiments, the solidifying step comprises exposure to a chemical coagulant, wherein the chemical coagulant is a solvent for the carbon nanotube solvent and a nonsolvent for the carbon nanotubes (such as acetone, water, tetrahydrofuran (THF), dimethyl sulfoxide (DMSO), ether, chloroform, and mixtures of sulfuric acid in water). Additionally or alternatively, a washing step may be performed to remove, e.g., residual traces of carbon nanotube solvent and/or by-products formed during the process.

In accordance with these embodiments, the carbon nanotube solvent is a solvent capable of dissolving the carbon nanotube starting material. Illustrative nanotube solvents include acids (e.g., chlorosulfonic acid (HSO₃Cl), fluorosulfonic acid, fluorosulfuric acid, hydrochloric acid, methanesulfonic acid, nitric acid, hydrofluoric acid, fluoroantimonic acid, magic acid, and other carborane-based acids) and supercritical fluids (e.g., supercritical carbon dioxide). As used herein, a supercritical fluid is a substance at a temperature and pressure above its critical point. In some embodiments, the solid solvent particles are frozen nanotube solvent particles, such as cryogenically frozen nanotube solvent particles.

In accordance with these embodiments, a solvent precursor material is a chemical compound that alone is incapable of dissolving the carbon nanotube starting material, but can be mixed with and/or reacted with a solvent activation agent to produce a carbon nanotube solvent. The solvent precursor material may be a solid material, such as phosphorous pentachloride in powder form, which may be activated use sulfuric acid as a solvent activation agent to obtain a carbon nanotube solvent.

In any of these different embodiments for connecting a CNT connector pad to a metal component, the method may further comprise additional steps to further connect CNT connector pad to the metal component, such as one or more or all of the following: applying and evaporating a solvent (such as one or more selected from water, acetone, methyl ethyl ketone, diethyl ether, chloroform, n-hexane, ethanol, ethylene glycol, xylene, toluene, THF (tetrahydrofuran), NMP (N-Methyl-2-pyrrolidone), and HFEs (hydrofluoroethers)) to promote densification via capillary action; applying pressure (optionally using a tape to provide mechanical compression, such as fluorinated ethylene propylene (FEP) tape with silicon adhesive); applying current (e.g., for resistive heating); and applying heat.

### Connecting a CNT-To-Metal Connector to a CNT Component or Metal Component

In some embodiments, an assembly as described herein comprises a CNT-to-metal connector, and a method of making such assembly comprises connecting a CNT-to-metal connector to a CNT component (e.g., a CNT component as described herein) directly or through a CNT connector pad (e.g., a CNT connector pad as described herein). In some embodiments, the method comprises connecting a CNT-to-metal connector to a metal component (e.g., a metal component as described herein).

In some embodiments, the method comprises contacting (i) a CNT component and (ii) a CNT-to-metal connector (optionally connected to a metal component (directly or through a CNT connector pad)) at an interface to form a junction of the assembly. In some embodiments, the method may comprise one or more or all of the following steps: wrapping (or tying including tying a knot) the junction with a CNT fiber or film; electroplating a surface of the CNT material of the CNT component with a metal (e.g., a metal comprises one or more selected from Cu, In, Ni, Ag, Au, Sn, Al, Zn, Pt, Pd, Pb, Mo, Mg, Rh, and W); sputter-coating a surface of the CNT material of the CNT component with a metal (e.g., a metal comprises one or more selected from Cu, In, Ni, Ag, Au, Sn, Al, Zn, Pt, Pd, Pb, Mo, Mg, Rh, and W); wetting a surface of the CNT material of the CNT component prior to a soldering or brazing step; soldering or brazing the CNT material of the CNT component to the CNT-to-metal connector; providing a conductive, metal-filled epoxy at the interface; and applying a reactive foil comprising a metal solder with one or more selected from pressure, current and heat at the interface. In some embodiments, the method may comprise potting, heat shrinking, or molding the assembly obtained from the aforementioned steps.

In some embodiments, the method comprises contacting (i) a CNT-to-metal connector (optionally connected to the CNT component (directly or through a CNT connector pad)) and (ii) the metal component at an interface to form a junction of the assembly. In some embodiments, the CNT-to-metal connector may comprise graphene, and the method may comprise a solidification step (e.g., drying the graphene). Additionally or alternatively, the CNT-to-metal connector may comprise epoxies (e.g., metal-containing epoxies), and the method may comprise a curing step.

In some embodiments, the method comprises soldering or brazing the CNT material (of the CNT component of CNT connector pad) to the CNT-to-metal connector or to the metal component. In some embodiments, the soldering or brazing is effected with a reactive metal foil (e.g., a reactive Al/Ni metal foil plated with a metal solder, such as a Sn solder).

In some embodiments, the method comprises, prior to the soldering or brazing step, wetting a surface of the CNT material. In some embodiments, wetting a surface of the CNT material comprises one or more of: (a) electroplating a surface of the CNT component with a metal (e.g., a metal comprises one or more selected from Cu, In, Ni, Ag, Au, Sn, Al, Zn, Pt, Pd, Pb, Mo, Mg, Rh, and W); and (b) sputter-coating a surface of the CNT component with a metal (e.g., a metal comprises one or more selected from Cu, In, Ni, Ag, Au, Sn, Al, Zn, Pt, Pd, Pb, Mo, Mg, Rh, and W); and (c) vapor depositing a surface of the CNT component with a metal (e.g., a metal comprises one or more selected from Cu, In, Ni, Ag, Au, Sn, Al, Zn, Pt, Pd, Pb, Mo, Mg, Rh, and W). In some embodiments, the method comprises providing a conductive, metal-filled epoxy (e.g., an Ag-filled epoxy) at the interface. In some embodiments, the method comprises wrapping (or tying, including tying a knot) the junction with a CNT fiber. In some embodiments, the method comprises potting, heat shrinking, or molding the assembly.

In accordance with some aspects, a CNT fiber or film used in a method for making an assembly (e.g., a CNT-to-metal assembly described herein) may be prepared from a CNT material as described herein.

### Exemplary Embodiments

The following exemplary embodiments are provided without being limiting.

Embodiment 1. An assembly comprising a carbon nanotube (CNT) component connected to a metal component, wherein the CNT component comprises a CNT material comprising at least 90 wt %, at least 95 wt %, or at least 99 wt % carbon nanotubes (CNTs), wherein the CNTs or CNT material exhibit one or more or all of the following properties: (a) the CNT material has an electrical conductivity of at least 1 MS/m, at least 5 MS/m, or at least 10 MS/m; (b) the CNTs have an average aspect ratio of at least 1000, at least 5000, or at least 10,000; and (c) the CNTs have an average G/D ratio of at least 1, at least 10, or at least 100.

Embodiment 2. The assembly of Embodiment 1, wherein the CNT component is connected to the metal component through a CNT-to-metal connector, wherein the CNT-to-metal connector comprises a material selected from graphene, metals, and metal-containing epoxies.

Embodiment 3. The assembly of Embodiment 1, wherein the CNT component is connected to the metal component through a CNT connector pad, wherein the CNT connector pad comprises a CNT material comprising at least 90 wt %, at least 95 wt %, or at least 99 wt % carbon nanotubes (CNTs), and wherein the CNTs or CNT material exhibit one or more or all of the following properties: (a) the CNT material has an electrical conductivity of at least 1 MS/m, at least 5 MS/m, or at least 10 MS/m; (b) the CNTs have an average aspect ratio of at least 1000, at least 5000, or at least 10,000; and (c) the CNTs have an average G/D ratio of at least 1, at least 10, or at least 100.

Embodiment 4. The assembly of Embodiment 3, wherein the CNT connector pad is connected to the metal component through a CNT-to-metal connector, wherein the CNT-to-metal connector comprises a material selected from graphene, metals, and metal-containing epoxies.

Embodiment 5. The assembly of Embodiment 3, wherein the CNT connector pad is comprised of a single layer of aligned or unaligned CNT material and has a thickness of from 1 to 10 μm.

Embodiment 6. The assembly of Embodiment 3, wherein the CNT connector pad is comprised of a plurality of layers of aligned CNT material and has a thickness of from 1 μm to 0.5 mm.

Embodiment 7. The assembly of Embodiment 3, wherein the CNT connector pad is comprised of a plurality of layers of aligned CNT material, wherein the plurality of layers comprises a first layer of said CNT material and a second layer of said CNT material, wherein said first and second layers are arranged in a different orientation relative to each other.

Embodiment 8. The assembly of Embodiment 3, wherein the CNT connector pad is comprised of a plurality of layers of aligned CNT material, wherein the plurality of layers comprises an outer layer of said CNT material and one or more intermediate layers of said CNT material, wherein one or more of said intermediate layers are sputter-coated or electroplated with a thin metal layer, optionally wherein the metal is one or more selected from Cu, In, Ni, Ag, Au, Sn, Al, Zn, Pt, Pd, Pb, Mo, Mg, Rh, and W, further optionally wherein the metal is selected from Cu, In, or Ni.

Embodiment 9. The assembly of any one of Embodiments 1-8, wherein the CNT material of the CNT component further exhibits one or more or all of the following properties: (i) the CNT material comprises less than 20 wt %, less than 10 wt %, or less than 5 wt % of non-sp2-hybridized carbon material, or non-sp2-hybridized carbon material is absent from the CNT material; (ii) the CNT material comprises less than 10 wt %, less than 5 wt %, or less than 2 wt % of metallic particle impurities, or metallic particle impurities are absent from the CNT material; and (iii) the CNT material has a density of at least 1 g/cm³, at least 1.2 g/cm³, or at least 1.4 g/cm³.

Embodiment 10. The assembly of any one of Embodiments 3-8, wherein the CNT material of the CNT connector pad further exhibits one or more or all of the following properties: (i) the CNT material comprises less than 20 wt %, less than 10 wt %, or less than 5 wt % of non-sp2-hybridized carbon material, or non-sp2-hybridized carbon material is absent from the CNT material; (ii) the CNT material comprises less than 10 wt %, less than 5 wt %, or less than 2 wt % of metallic particle impurities, or metallic particle impurities are absent from the CNT material; and (iii) the CNT material has a density of at least 1 g/cm³, at least 1.2 g/cm³, or at least 1.4 g/cm³.

Embodiment 11. The assembly of any one of the preceding Embodiments, wherein the CNT component is in a form selected from a film, a fiber, a foam, and a coating.

Embodiment 12. The assembly of any one of the preceding Embodiments, wherein the metal component is selected from a metal matrix, metal wires, metal cables, ring terminals, circuit board terminals, quick-disconnect terminals, spade terminals, hook terminals, snap plug terminals, battery terminals, battery terminal clamps, battery springs, grounding blocks, butt splices, wire ferrules, terminal blocks, compression lugs, set screw lugs, BNC (Bayonet Neill-Concelman) connectors, RCA (Radio Corporation of America) connectors, SMA (SubMiniature version A) connectors, and F-type connectors.

Embodiment 13. The assembly of any one of the preceding Embodiments, wherein the CNT component is selected from display electrodes, touch screen electrodes, energy harvesting electrodes, solar cell electrodes, battery electrodes, static-dissipative elements, grounding elements, resistive heating elements, strain sensing elements, chemical sensor elements, the radiating element of an antenna, the ground plane of an antenna, the outer shield of a coaxial cable, the inner conductor of a coaxial cable, smart coatings for in-situ monitoring of abrasion, resistive elements for sensors, capacitive elements for sensors, inductive elements for sensors, biosensing elements for muscular activity, biosensing elements for neural activity, muscular stimulation electrodes, neural stimulation electrodes, DC power cables, DC transmission lines, AC power cables, A/C transmission lines, field emitters, transformer coils, DC motor coils, electronic textiles, transistors, conductors, capacitors, and inductors.

Embodiment 14. The assembly of any one of the preceding Embodiments, wherein the assembly exhibits one or more or all of the following properties: (i) a signal attenuation of 20 dB to 30 dB, 10 dB to 20 dB, or 5 dB to 10 dB; (ii) a signal to noise ratio of 2:1 to 5:1, 5:1 to 20:1, or 20:1 to 100:1; (iii) a phase shift relative to the signal going into the assembly of less than pi/12 rad, less than pi/24 rad, or less than pi/96 rad; and (iv) a temperature difference as compared to the steady state temperature of the metal component of less than 25° C., less than 15° C., or less than 5° C.

Embodiment 15. A method of making the assembly of any one of the preceding Embodiments, comprising contacting the CNT component and the metal component at an interface to form a junction, and further comprising one or more or all of the following steps: wrapping or tying the junction with a CNT fiber or film or foam; electroplating a surface of the CNT material of the CNT component with a metal; sputter-coating a surface of the CNT material of the CNT component with a metal; wetting a surface of the CNT material of the CNT component prior to a soldering or brazing step; soldering or brazing the CNT material of the CNT component to the metal component; providing a conductive, metal-filled epoxy at the interface; applying a reactive foil comprising a metal solder with one or more selected from pressure, current and heat at the interface; and potting, heat shrinking, or molding the assembly.

Embodiment 16. A method of making the assembly of Embodiment 2, comprising contacting the CNT component and the CNT-to-metal connector at an interface to form a junction, and further comprising one or more or all of the following steps: wrapping or tying the junction with a CNT fiber or film or foam; electroplating a surface of the CNT material of the CNT component with a metal; sputter-coating a surface of the CNT material of the CNT component with a metal; wetting a surface of the CNT material of the CNT component prior to a soldering or brazing step; soldering or brazing the CNT material of the CNT component to the CNT-to-metal connector; providing a conductive, metal-filled epoxy at the interface; applying a reactive foil comprising a metal solder with one or more selected from pressure, current and heat at the interface; and potting, heat shrinking, or molding the assembly.

Embodiment 17. The method of Embodiment 15 or Embodiment 16, wherein the metal is one or more selected from Cu, In, Ni, Ag, Au, Sn, Al, Zn, Pt, Pd, Pb, Mo, Mg, Rh, and W, optionally wherein the metal is selected from Cu, In, or Ni.

Embodiment 18. A method of making the assembly of any one of Embodiments 3-8, comprising contacting the CNT component and the CNT connector pad at an interface, and further comprising one or more or all of the following steps: evaporating a solvent at the interface to connect the CNT component to the CNT connector pad via capillary action, optionally wherein the solvent is one or more selected from water, acetone, methyl ethyl ketone, diethyl ether, chloroform, n-hexane, ethanol, ethylene glycol, xylene, toluene, THF (tetrahydrofuran), NMP (N-Methyl-2-pyrrolidone), and HFEs (hydrofluoroethers); solvent-welding the CNT connector pad to the CNT component using an acid; and mechanically attaching the CNT connector pad to the CNT component.

Embodiment 19. The method of Embodiment 18, further comprising contacting CNT connector pad and the metal component at an interface to form a junction of the assembly, and further comprising one or more or all of the following steps: wrapping or tying the junction with a CNT fiber or film or foam; electroplating a surface of the CNT material of the CNT connector pad with a metal; sputter-coating a surface of the CNT material of the CNT connector pad with a metal; wetting a surface of the CNT material of the CNT connector pad prior to a soldering or brazing step; soldering or brazing the CNT material of the CNT connector pad to the metal component; providing a conductive, metal-filled epoxy at the interface; applying a reactive foil comprising a metal solder with one or more selected from pressure, current and heat at the interface; and potting, heat shrinking, or molding the assembly.

Embodiment 20. The method of Embodiment 19, wherein the metal is one or more selected from Cu, In, Ni, Ag, Au, Sn, Al, Zn, Pt, Pd, Pb, Mo, Mg, Rh, and W, optionally wherein the metal is selected from Cu, In, or Ni.

Embodiment 21. A method of making the assembly of any one of Embodiments 3 and 5-8, comprising providing a CNT connector pad on a surface of a metal component by: wrapping or tying a pre-formed CNT film or foam around the metal component; wrapping or tying a CNT fiber around the metal component; or forming a CNT film directly on a surface of the metal component from a fluid phase.

Embodiment 22. A method of making the assembly of any one of Embodiments 3 and 5-8, comprising: (i) loading a transfer sleeve with a pre-formed CNT film or CNT foam, optionally wherein the loading (a) comprises one or more or all of the following steps: providing the CNT film or CNT foam around a support; wetting an inside surface of the transfer sleeve; inserting the support into the transfer sleeve; compressing the transfer sleeve onto/around the support; and withdrawing the support from the transfer sleeve to obtain the CNT film- or CNT-foam-loaded sleeve; or (b) comprises preparing the CNT film or CNT foam in situ inside the transfer sleeve by forming the CNT film or CNT foam directly on interior surfaces of the transfer sleeve from a fluid phase; and (ii) transferring the CNT film or CNT foam from the transfer sleeve to a metal component, optionally wherein the transferring comprises one or more or all of the following steps: wetting a surfaces of the metal component; inserting the metal component into the CNT film- or CNT foam-loaded sleeve; compressing the sleeve onto/around the metal component; and withdrawing the sleeve from the metal component to obtain the metal component provided with a CNT connector pad comprised of the CNT film or CNT foam.

Embodiment 23. The method of any one of Embodiments 19-22, further comprising promoting connection between the CNT connector pad and metal component by one or more of the following steps: evaporating a solvent at an interface between the CNT connector pad and metal component to promote densification via capillary action, optionally wherein the solvent is one or more selected from water, acetone, methyl ethyl ketone, diethyl ether, chloroform, n-hexane, ethanol, cthylene glycol, xylene, toluene, THF (tetrahydrofuran), NMP (N-Methyl-2-pyrrolidone), and HFEs (hydrofluoroethers); applying pressure to the interface; applying current to the interface; and applying heat to the interface.

Embodiment 24. The method of any one of Embodiments 21-23, further comprising contacting the CNT component and the CNT connector pad at an interface, and promoting connection between the CNT component and CNT connector pad by one or more or all of the following steps: evaporating a solvent at an interface between the CNT connector pad and CNT component to promote densification via capillary action, optionally wherein the solvent is one or more selected from water, acetone, methyl ethyl ketone, diethyl ether, chloroform, n-hexane, ethanol, cthylene glycol, xylene, toluene, THF (tetrahydrofuran), NMP (N-Methyl-2-pyrrolidone), and HFEs (hydrofluoroethers); solvent-welding the CNT connector pad to the CNT component using an acid; and mechanically attaching the CNT connector pad to the CNT component.

Embodiment 25. An assembly comprising a carbon nanotube (CNT) component connected to a CNT connector pad, wherein each of the CNT component and the CNT connector pad independently comprises a CNT material comprising at least 90 wt %, at least 95 wt %, or at least 99 wt % carbon nanotubes (CNTs), wherein the CNTs or CNT material exhibit one or more or all of the following properties: the CNT material has an electrical conductivity of at least 1 MS/m, at least 5 MS/m, or at least 10 MS/m; the CNTs have an average aspect ratio of at least 1000, at least 5000, or at least 10,000; and the CNTs have an average G/D ratio of at least 1, at least 10, or at least 100.

Embodiment 26. An assembly comprising a metal component connected to a CNT connector pad, wherein the CNT connector pad comprises a CNT material comprising at least 90 wt %, at least 95 wt %, or at least 99 wt % carbon nanotubes (CNTs), wherein the CNTs or CNT material exhibit one or more or all of the following properties: the CNT material has an electrical conductivity of at least 1 MS/m, at least 5 MS/m, or at least 10 MS/m; the CNTs have an average aspect ratio of at least 1000, at least 5000, or at least 10,000; and the CNTs have an average G/D ratio of at least 1, at least 10, or at least 100.

Embodiment 27. The assembly of any one of Embodiments 1-14 and 26 or the method of any one of Embodiments 15-24, wherein the metal component comprises one or more metals selected from Cu, In, Ni, Ag, Au, Sn, Al, Zn, Pt, Pd, Pb, Mo, Mg, Rh, and W.

### EXAMPLES

### Example 1. Mechanical Fastening

Example 1a. Preparation of CNT film. CNT films (˜4 μm thick) were fabricated from CNT materials using a doctor blade coating method according to a method described in U.S. Pat. No. 11,111,146, which is incorporated by reference in its entirety.

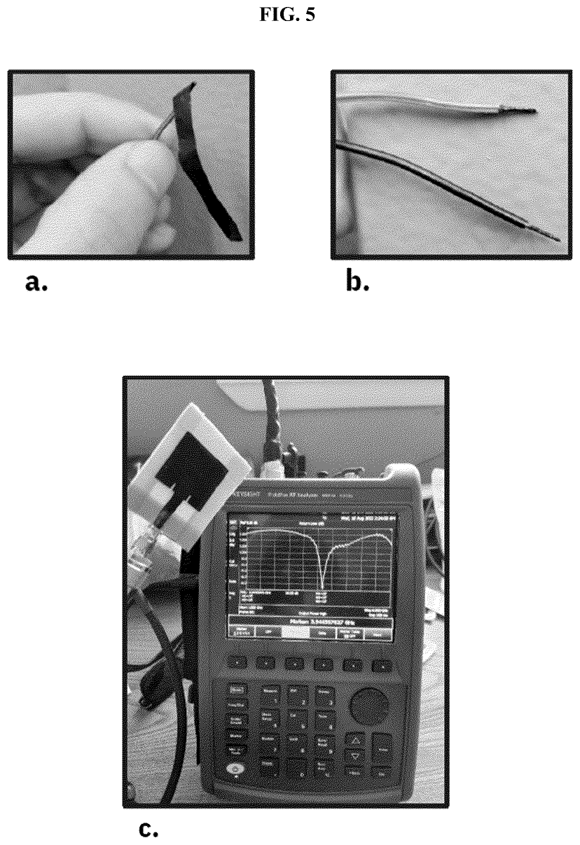

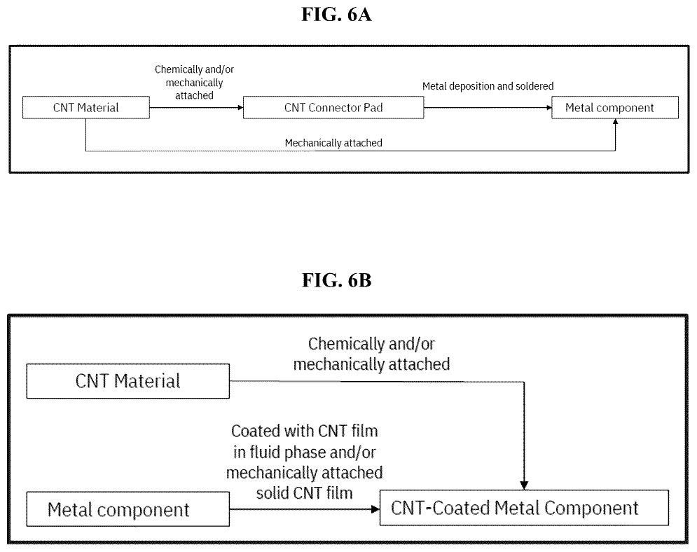

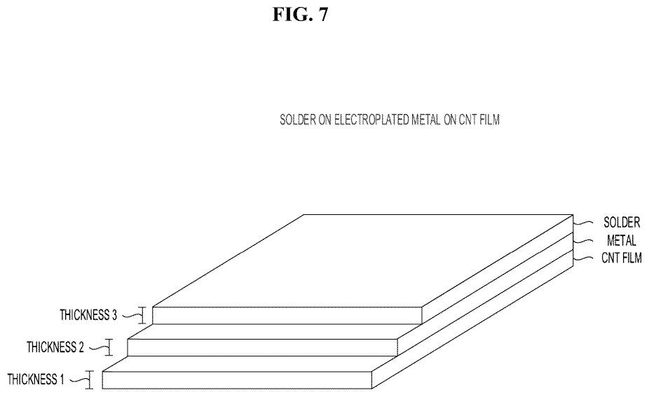

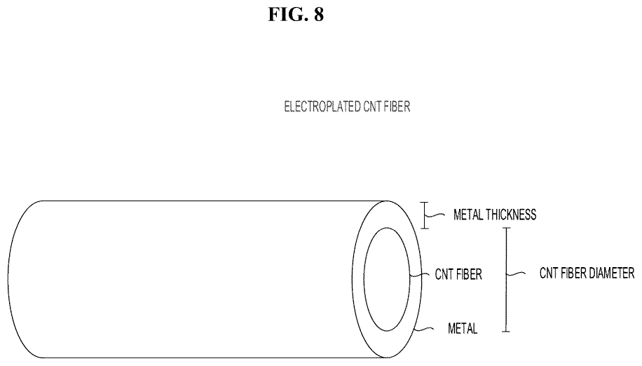

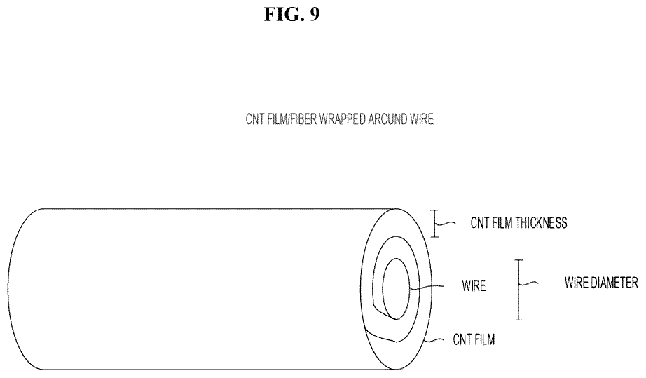

Example 1b. Preparation of SMA connector for mechanical fastening to a CNT antenna. The center pin and ground legs of a SMA connector (SubMiniature version A connector) were each individually wrapped with CNT film fabricated according to Example 1a until the thickness reached approximately 100 μm around the connector elements to form a CNT connector pad. The wrapped CNT film (CNT connector pad) was then exposed to an acetone mist and pressure was applied to compress the wrapped film down to a thickness of less than 70 μm. Evaporation of the acetone improves the film's adhesion, e.g., strengthen the connection between the CNT connector pad and the SMA connector. The CNT film-wrapped SMA connector was fitted over the dielectric substrate of a CNT patch antenna, such that the center pin of the CNT film-wrapped SMA connector was in close contact with the radiating element and the ground legs of the CNT film-wrapped SMA connector were in close contact with the ground plane element. Fluorinated Ethylene Propylene (FEP) tape with silicon adhesive (50 μm thick) was applied over these areas to provide mechanical compression. A potting compound was applied over the tape to mechanically secure the connection area (FIG. 5).

### Example 2. Electroplating Copper Pads

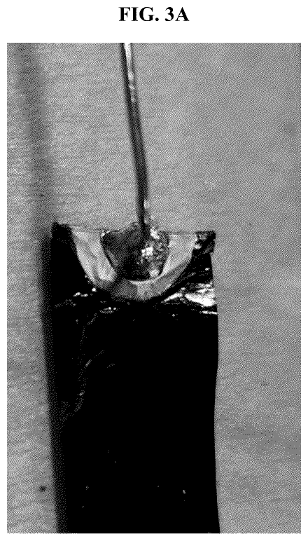

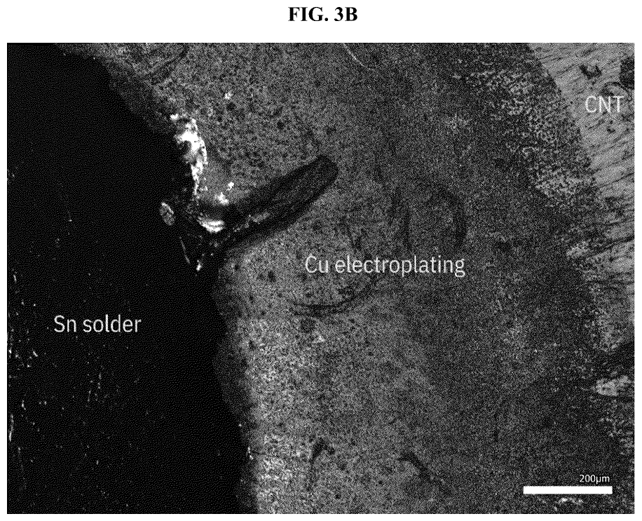

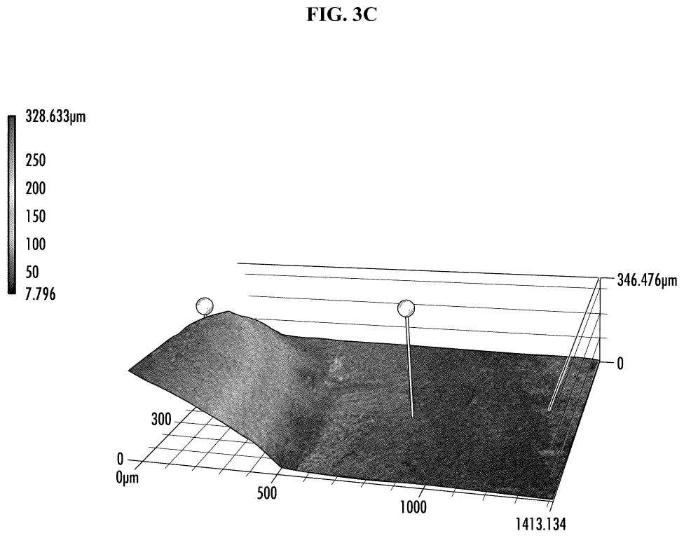

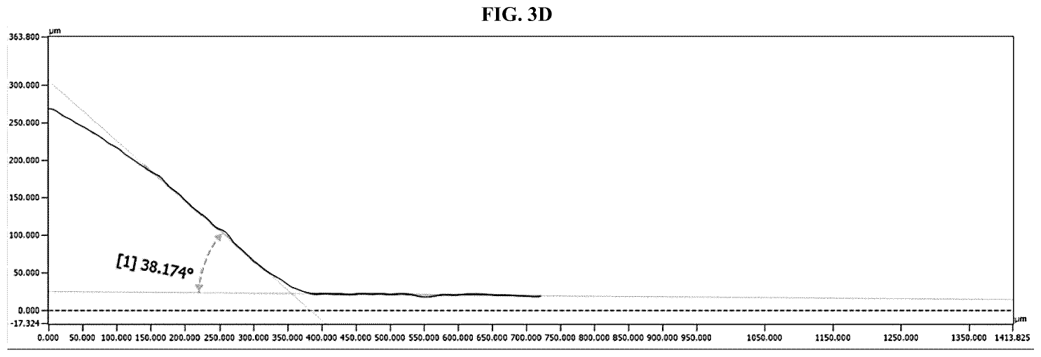

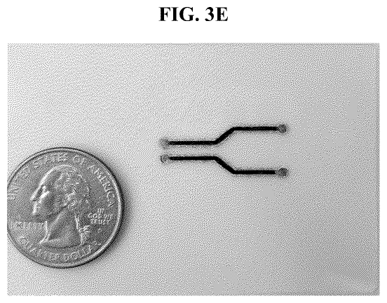

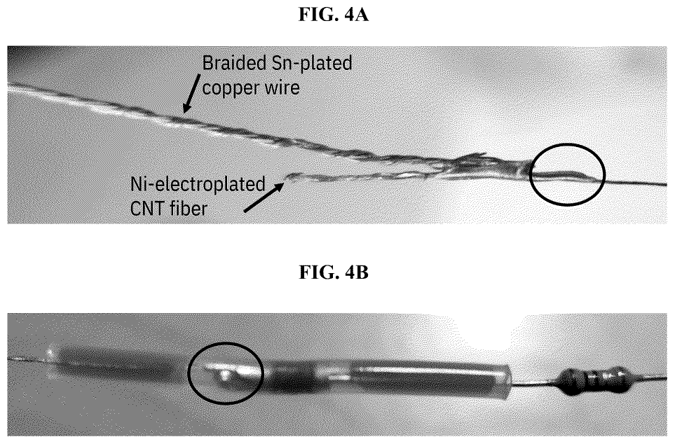

A CNT transmission line with 2 mm wide traces terminating in CNT connector pads (5 mm in diameter) was laser-cut from a 4 μm thick CNT film prepared according to Example 1a. See FIG. 3C. Thus, the CNT connector pad was a region of the CNT component (CNT transmission line).

Electroplating. Copper-plated CNT connector pads were prepared as follows on the transmission line. Droplets of electroplating solution (20% w/w aqueous copper sulfate (CuSO₄) solution) were deposited on each of the four CNT connector pads, such that the CNT connector pads were covered by the electroplating solution. A DC supply was connected to CNT material of the transmission line via a spring-loaded gold-plated connector pin wherein the contact surface of the pin had a diameter of 2 mm. A copper wire (18 American Wire Gauge, served as anode) was gently brought into contact with the topmost surface of the droplets while a DC voltage of 1.2 V was applied in constant voltage mode (FIG. 3E).

### Example 3. Soldering

Soldering between copper-plated CNT connector pads prepared as described above and resistor legs for contact resistance testing was accomplished using lead-free tin solder and indium solder, as well as reactive indium foil (such as NanoFoil® from Indium Corporation, a reactive multi-layer foil fabricated by vapor-depositing alternating nanoscale layers of Al Ni). The solders were applied using conventional techniques. NanoFoil® was activated using the hot tip of a nichrome wire heating element. Soldering with lead-free tin solder produced the solder droplet and contact angle shown in FIGS. 3A-3D.

### Example 4. Resistance Measurements

Measurement setup-Method A. Two lead wires were soldered to either end of a Cu pad electroplated on two CNT films prepared analogously to Example 2 above, but using CNT film instead of CNT transmission line as a substrate. The CNT films were connected to a 10 Ω resistor via the electroplated Cu pads onto which the resistor legs were soldered. A total series resistance of 11.38 Ω was observed using a Keysight 34461A multimeter. Separately, a resistance of 10.33 Ω was observed for the resistor. After subtracting the measured resistance of the CNT films, the remaining difference (attributed to four contact resistances of the soldered wires and resistor legs on the electroplated Cu pads) was less than the measurement uncertainty of the multimeter. The negligible contact resistance demonstrates the CNT connections provided good electrical contact with no losses.

Measurement setup-Method B. Two lead wires were wrapped in CNT film and mechanically attached to two bare ends of CNT fiber, analogously to Example 1a above. The other ends of the wrapped lead wires were electroplated and connected to a 10 Ω resistor via solder-loaded heat shrink tubing (FIG. 5). A total series resistance of 12.48 Ω was observed using a Keysight 34461A multimeter. Separately, a resistance of 10.12 Ω was observed for the resistor. After subtracting the measured resistances of the CNT fibers, the remaining difference (attributed to the following four contact resistances: two contact resistances of the electroplated CNT fibers and the resistor legs, and two contact resistances of the mechanically attached CNT fibers with the CNT-wrapped lead wires) was less than the measurement uncertainty of the multimeter. The negligible contact resistance demonstrates the CNT connections provided good electrical contact with no losses.

### Example 5. Method Using Transfer Sleeve

A transfer sleeve designed to mate with a 1 mm×1 mm square metal pin that has an exposed length of 5 mm is used to prove a CNT connector pad on the metal pin. The transfer sleeve has internal dimensions of 1.1 mm×1.1 mm and a length of 3 mm.

A pre-formed CNT film is wrapped around a PTFE support (rod) that has the same cross-sectional dimensions as the metal pin and is twice the length of the transfer sleeve. The CNT film is wrapped around the support to cover a 3 mm length of the support, which corresponds to the inner length of the sleeve. See FIG. 10, panel a.

Transfer of CNT film from support to sleeve: The inner surface of the sleeve is wetted with water to facilitate transfer of the CNT film from the support to the sleeve. The support is inserted into the sleeve, the sleeve is compressed about the support to promote contact with and transfer of the CNT film from the support to the sleeve, and the sleeve is removed, leaving the CNT film in the sleeve. See FIG. 10, panels b-c.

Transfer of CNT film from sleeve to metal pin: The film is transferred to the metal pin using a similar procedure. The metal pin is wetted with water to facilitate transfer of the CNT film from the sleeve to the metal pin. The sleeve is mated to the metal pin (i.e., placed over it) and compressed about the metal pin to promote contact with and transfer of the CNT film from the sleeve to the metal pin. Then, the sleeve is withdrawn from the metal pin, which is now coated with the CNT film and can serve as a CNT connector pad on the metal pin. See FIG. 10, panels d-c.

Optionally, further steps are conducted to ensure that the CNT film (CNT connector pad) remains on the metal pin until it is connected to a CNT component, such as one or more of wetting with water, wetting with acetone, heating, compression, etc. See FIG. 10, panel f.

What is claimed is:

1. An assembly comprising a carbon nanotube (CNT) component connected to a metal component, wherein the CNT component comprises a CNT material comprising at least 90 wt %, at least 95 wt %, or at least 99 wt % carbon nanotubes (CNTs), wherein the CNTs or CNT material exhibit one or more or all of the following properties:
(a) the CNT material has an electrical conductivity of at least 1 MS/m, at least 5 MS/m, or at least 10 MS/m;
(b) the CNTs have an average aspect ratio of at least 1000, at least 5000, or at least 10,000; and
(c) the CNTs have an average G/D ratio of at least 1, at least 10, or at least 100.

2. The assembly of claim 1, wherein the CNT component is connected to the metal component through a CNT-to-metal connector, wherein the CNT-to-metal connector comprises a material selected from graphene, metals, and metal-containing epoxies.

3. The assembly of claim 1, wherein the CNT component is connected to the metal component through a CNT connector pad, wherein the CNT connector pad comprises a CNT material comprising at least 90 wt %, at least 95 wt %, or at least 99 wt % carbon nanotubes (CNTs), and wherein the CNTs or CNT material exhibit one or more or all of the following properties:
(a) the CNT material has an electrical conductivity of at least 1 MS/m, at least 5 MS/m, or at least 10 MS/m;
(b) the CNTs have an average aspect ratio of at least 1000, at least 5000, or at least 10,000; and
(c) the CNTs have an average G/D ratio of at least 1, at least 10, or at least 100.

4. The assembly of claim 3, wherein the CNT connector pad is connected to the metal component through a CNT-to-metal connector, wherein the CNT-to-metal connector comprises a material selected from graphene, metals, and metal-containing epoxies.

5. The assembly of claim 3, wherein the CNT connector pad is selected from (i) a CNT connector pad comprised of a single layer of aligned or unaligned CNT material having a thickness of from 1 to 10 μm and (ii) a CNT connector pad comprised of a plurality of layers of aligned CNT material having a thickness of from 1 μm to 0.5 mm.

6. The assembly of claim 3, wherein the CNT connector pad is comprised of a plurality of layers of aligned CNT material, wherein the plurality of layers comprises a first layer of said CNT material and a second layer of said CNT material, wherein said first and second layers are arranged in a different orientation relative to each other.

7. The assembly of claim 3, wherein the CNT connector pad is comprised of a plurality of layers of aligned CNT material, wherein the plurality of layers comprises an outer layer of said CNT material and one or more intermediate layers of said CNT material, wherein one or more of said intermediate layers are sputter-coated or electroplated with a thin metal layer, optionally wherein the metal is one or more selected from Cu, In, Ni, Ag, Au, Sn, Al, Zn, Pt, Pd, Pb, Mo, Mg, Rh, and W, further optionally wherein the metal is selected from Cu, In, or Ni.

8. The assembly of claim 3, wherein the CNT material of one or both of the CNT component and the CNT connector pad further exhibits one or more or all of the following properties:
(i) the CNT material comprises less than 20 wt %, less than 10 wt %, or less than 5 wt % of non-sp2-hybridized carbon material, or non-sp2-hybridized carbon material is absent from the CNT material;
(ii) the CNT material comprises less than 10 wt %, less than 5 wt %, or less than 2 wt % of metallic particle impurities, or metallic particle impurities are absent from the CNT material; and
(iii) the CNT material has a density of at least 1 g/cm³, at least 1.2 g/cm³, or at least 1.4 g/cm³.

9. The assembly of claim 3, wherein the CNT component is in a form selected from a film, a fiber, a foam, and a coating.

10. The assembly of claim 3, wherein the metal component is selected from a metal matrix, metal wires, metal cables, ring terminals, circuit board terminals, quick-disconnect terminals, spade terminals, hook terminals, snap plug terminals, battery terminals, battery terminal clamps, battery springs, grounding blocks, butt splices, wire ferrules, terminal blocks, compression lugs, set screw lugs, BNC (Bayonet Neill-Concelman) connectors, TNC (Threaded Neill-Concelman) connectors, RCA (Radio Corporation of America) connectors, SMA (SubMiniature version A) connectors, SMC (SubMiniature version C) connectors, FFC (Flat Flexible Cable) connectors, FPC (Flexible Printed Circuit) connectors, DIN (Deutsches Institut fur Normung) connectors, and F-type connectors.

11. The assembly of claim 3, wherein the CNT component is selected from display electrodes, touch screen electrodes, energy harvesting electrodes, solar cell electrodes, battery electrodes, static-dissipative elements, grounding elements, resistive heating elements, strain sensing elements, chemical sensor elements, the radiating element of an antenna, the ground plane of an antenna, the outer shield of a coaxial cable, the inner conductor of a coaxial cable, smart coatings for in-situ monitoring of abrasion, resistive elements for sensors, capacitive elements for sensors, inductive elements for sensors, biosensing elements for muscular activity, biosensing elements for neural activity, muscular stimulation electrodes, neural stimulation electrodes, DC power cables, DC transmission lines, AC power cables, A/C transmission lines, field emitters, transformer coils, DC motor coils, electronic textiles, resistors, transistors, conductors, capacitors, and inductors.

12. The assembly of claim 3, wherein the assembly exhibits one or more or all of the following properties:
a signal attenuation of 20 dB to 30 dB, 10 dB to 20 dB, or 5 dB to 10 dB;
a signal to noise ratio of 2:1 to 5:1, 5:1 to 20:1, or 20:1 to 100:1;
a phase shift relative to the signal going into the assembly of less than pi/12 rad, less than pi/24 rad, or less than pi/96 rad; and
a temperature difference as compared to the steady state temperature of the metal component of less than 25° C., less than 15° C., or less than 5° C.

13. A method of making the assembly of claim 1, comprising contacting the CNT component and the metal component at an interface to form a junction, and further comprising one or more or all of the following steps:
wrapping or tying the junction with a CNT fiber or film or foam;
electroplating a surface of the CNT material of the CNT component with a metal;
sputter-coating a surface of the CNT material of the CNT component with a metal;
wetting a surface of the CNT material of the CNT component prior to a soldering or brazing step;
soldering or brazing the CNT material of the CNT component to the metal component;
providing a conductive, metal-filled epoxy at the interface;
applying a reactive foil comprising a metal solder with one or more selected from pressure, current and heat at the interface; and
potting, heat shrinking, or molding the assembly.

14. A method of making the assembly of claim 2, comprising contacting the CNT component and the CNT-to-metal connector at an interface to form a junction, and further comprising one or more or all of the following steps:
wrapping or tying the junction with a CNT fiber or film or foam;
electroplating a surface of the CNT material of the CNT component with a metal;
sputter-coating a surface of the CNT material of the CNT component with a metal;
wetting a surface of the CNT material of the CNT component prior to a soldering or brazing step;
soldering or brazing the CNT material of the CNT component to the CNT-to-metal connector;
providing a conductive, metal-filled epoxy at the interface;
applying a reactive foil comprising a metal solder with one or more selected from pressure, current and heat at the interface; and
potting, heat shrinking, or molding the assembly.

15. A method of making the assembly of claim 3, comprising contacting the CNT component and the CNT connector pad at an interface, and further comprising one or more or all of the following steps:
evaporating a solvent at the interface to connect the CNT component to the CNT connector pad via capillary action, optionally wherein the solvent is one or more selected from water, acetone, methyl ethyl ketone, diethyl ether, chloroform, n-hexane, ethanol, ethylene glycol, xylene, toluene, THF (tetrahydrofuran), NMP (N-Methyl-2-pyrrolidone), and HFEs (hydrofluoroethers);
solvent-welding the CNT connector pad to the CNT component using an acid; and
mechanically attaching the CNT connector pad to the CNT component.

16. A method of making the assembly of claim 3, comprising providing a CNT connector pad on a surface of a metal component by:
wrapping or tying a pre-formed CNT film or foam around the metal component;
wrapping or tying a CNT fiber around the metal component; or
forming a CNT film directly on a surface of the metal component from a fluid phase.

17. A method of making the assembly of claim 3, comprising:
(i) loading a transfer sleeve with a pre-formed CNT film or CNT foam, optionally wherein the loading (a) comprises one or more or all of the following steps: providing the CNT film or CNT foam around a support; wetting an inside surface of the transfer sleeve; inserting the support into the transfer sleeve; compressing the transfer sleeve onto/around the support; and withdrawing the support from the transfer sleeve to obtain the CNT film- or CNT-foam-loaded sleeve; or (b) comprises preparing the CNT film or CNT foam in situ inside the transfer sleeve by forming the CNT film or CNT foam directly on interior surfaces of the transfer sleeve from a fluid phase; and
(ii) transferring the CNT film or CNT foam from the transfer sleeve to a metal component, optionally wherein the transferring comprises one or more or all of the following steps: wetting a surfaces of the metal component; inserting the metal component into the CNT film- or CNT foam-loaded sleeve; compressing the sleeve onto/around the metal component; and withdrawing the sleeve from the metal component to obtain the metal component provided with a CNT connector pad comprised of the CNT film or CNT foam.

18. An assembly comprising a carbon nanotube (CNT) component connected to a CNT connector pad, wherein each of the CNT component and the CNT connector pad independently comprises a CNT material comprising at least 90 wt %, at least 95 wt %, or at least 99 wt % carbon nanotubes (CNTs), wherein the CNTs or CNT material exhibit one or more or all of the following properties:
the CNT material has an electrical conductivity of at least 1 MS/m, at least 5 MS/m, or at least 10 MS/m;
the CNTs have an average aspect ratio of at least 1000, at least 5000, or at least 10,000; and
the CNTs have an average G/D ratio of at least 1, at least 10, or at least 100.

19. An assembly comprising a metal component connected to a CNT connector pad, wherein the CNT connector pad comprises a CNT material comprising at least 90 wt %, at least 95 wt %, or at least 99 wt % carbon nanotubes (CNTs), wherein the CNTs or CNT material exhibit one or more or all of the following properties:
the CNT material has an electrical conductivity of at least 1 MS/m, at least 5 MS/m, or at least 10 MS/m;
the CNTs have an average aspect ratio of at least 1000, at least 5000, or at least 10,000; and
the CNTs have an average G/D ratio of at least 1, at least 10, or at least 100.

20. The assembly of claim 1, wherein the metal component comprises one or more metals selected from Cu, In, Ni, Ag, Au, Sn, Al, Zn, Pt, Pd, Pb, Mo, Mg, Rh, and W.
